(19) United States
(12) Patent Application Publication
(10) Pub. No.: US 2025/0301645 A1
(43) Pub. Date: Sep. 25, 2025

(54) SEMICONDUCTOR DEVICES AND ELECTRONIC SYSTEMS INCLUDING THE SAME

(71) Applicant: Samsung Electronics Co., Ltd., Suwon-si (KR)

(72) Inventors: SEONGJUN SEO, Suwon-si (KR); SEOKCHEON BAEK, Suwon-si (KR)

(21) Appl. No.: 18/907,732

(22) Filed: Oct. 7, 2024

(30) Foreign Application Priority Data
Mar. 20, 2024 (KR) 10-2024-0038717

(51) Int. Cl. H10B 43/27; H01L 25/065; H10B 43/10; H10B 43/35; H10B 80/00

(52) U.S. Cl. CPC H10B 43/27; H01L 25/0652; H10B 43/10; H10B 43/35; H10B 80/00; H01L 2225/0651

(57) ABSTRACT

A semiconductor device comprising: a first conductive pattern; a second conductive pattern on the first conductive pattern; a connection contact structure and a parity contact structure in the second conductive pattern and are connected to the first conductive pattern; wherein the connection contact structure includes: a connection contact; and a connection contact dielectric layer extending around the connection contact, wherein the parity contact structure includes: a parity contact; and a parity contact dielectric layer extending around the parity contact, wherein the parity contact dielectric layer includes: a sidewall part in contact with an upper surface of the first conductive pattern and a sidewall of the second conductive pattern; and a connection part connected to the sidewall part, wherein a lower surface of the connection part of the parity contact dielectric layer is in contact with an upper surface of the second conductive pattern.

### CROSS-REFERENCE TO RELATED APPLICATIONS

This U.S. nonprovisional application claims priority under 35 U.S.C § 119 to Korean Patent Application No. 10-2024-0038717 filed on Mar. 20, 2024 in the Korean Intellectual Property Office, the disclosure of which is hereby incorporated by reference in its entirety.

### BACKGROUND OF THE INVENTION

The present inventive concepts relate to semiconductor devices and electronic systems including the same, and more particularly, to semiconductor devices including a parity contact structure and electronic systems including the same.

A semiconductor device attracts attention as an important element in the electronics industry because of its properties such as compactness, multi-functionality, and/or low manufacturing cost. Semiconductor devices may encompass semiconductor memory devices storing logic data, semiconductor logic devices processing operations of logic data, and hybrid semiconductor devices having both memory and logic elements.

Recently, high speed and low power consumption of electronic products may need that semiconductor devices embedded in the electronic products should have high operating speed and/or lower operating voltage. However, an increase in integration of semiconductor devices may cause a reduction (e.g., a degradation) in electrical properties and production yield of semiconductor devices. Therefore, many studies have been conducted to increase (e.g., improve) electrical properties and production yield of semiconductor devices.

### SUMMARY OF THE INVENTION

Some embodiments of the present inventive concepts provide a semiconductor device with increased reliability and improved electrical properties and an electronic system including the same.

According to some embodiments of the present inventive concepts, a semiconductor device, comprising: a first conductive pattern; a second conductive pattern spaced apart in a first direction from the first conductive pattern, wherein the first direction is perpendicular to an upper surface of the first conductive pattern; a memory channel structure that extends in the first conductive pattern and the second conductive pattern in the first direction; a first connection contact structure that extends in the second conductive pattern in the first direction and is electrically connected to the first conductive pattern; and a first parity contact structure that extends in the second conductive pattern in the first direction and is electrically connected to the first conductive pattern, wherein the first connection contact structure includes: a first connection contact; and a first connection contact dielectric layer that extends around the first connection contact, wherein the first parity contact structure includes: a first parity contact; and a first parity contact dielectric layer that extends around the first parity contact, wherein the first parity contact dielectric layer includes: a sidewall part in contact with the upper surface of the first conductive pattern and a first sidewall of the second conductive pattern; and a connection part connected to the sidewall part, wherein a lower surface of the connection part of the first parity contact dielectric layer is in contact with an upper surface of the second conductive pattern.

According to some embodiments of the present inventive concepts, a semiconductor device, comprising: a gate stack structure that includes a plurality of conductive patterns including a first conductive pattern; a memory channel structure that extends in the gate stack structure; a first connection contact structure electrically connected to the first conductive pattern; and a first parity contact structure electrically connected to the first conductive pattern, wherein the first connection contact structure includes: a first connection contact; and a first connection contact dielectric layer that extends around the first connection contact, wherein the first parity contact structure includes: a first parity contact; and a first parity contact dielectric layer that extends around the first parity contact, wherein the first parity contact includes a first part and a second part on the first part, and wherein the second part of the first parity contact includes a lower surface that connects a sidewall of the first part of the first parity contact to a sidewall of the second part of the first parity contact.

According to some embodiments of the present inventive concepts, An electronic system, comprising: a main board; a semiconductor device on the main board; and a controller on the main board and electrically connected to the semiconductor device, wherein the semiconductor device includes: a first conductive pattern; a second conductive pattern spaced apart in a first direction from the first conductive pattern, wherein the first direction is perpendicular to an upper surface of the first conductive pattern; a third conductive pattern spaced apart in the first direction from the second conductive pattern; a memory channel structure that extends in the first, second, and third conductive patterns in the first direction; a first connection contact structure electrically connected to the first conductive pattern; a first parity contact structure electrically connected to the first conductive pattern; a second connection contact structure that extends in the first conductive pattern in the first direction and is electrically connected to the second conductive pattern; a second parity contact structure that extends in the first conductive pattern in the first direction and is electrically connected to the second conductive pattern; a third connection contact structure that extends in the first and second conductive patterns in the first direction and is electrically connected to the third conductive pattern; and a third parity contact structure that extends in the first and second conductive patterns in the first direction and is electrically connected to the third conductive pattern, wherein each of the first, second, and third connection contact structures includes a connection contact and a connection contact dielectric layer that extends around the connection contact, wherein the first parity contact structure includes a first parity contact and a first parity contact dielectric layer that extends around the first parity contact, wherein the second parity contact structure includes a second parity contact and a second parity contact dielectric layer that extends around the second parity contact, wherein the third parity contact structure includes a third parity contact and a third parity contact dielectric layer that extends around the third parity contact, wherein the third parity contact includes a first part, a second part on the first part, and a third part on the second part, wherein a maximum width of the first part of the third parity contact in a second direction is less than a minimum width of the second part of the third parity contact in the second direction, wherein a maximum width of the second part of the third parity contact in the second direction is less than a minimum width of the third part of the third parity contact in the second direction, wherein the second parity contact includes a first part and a second part on the first part of the second parity contact, wherein a maximum width of the first part of the second parity contact in the second direction is less than a minimum width of the second part of the second parity contact in the second direction, wherein a minimum width of the first part of the third parity contact in the second direction is less than a minimum width of the first part of the second parity contact in the second direction, and wherein the second direction is parallel with the upper surface of the first conductive pattern.

### BRIEF DESCRIPTION OF DRAWINGS

FIG. 1A illustrates a simplified block diagram showing an electronic system including a semiconductor device according to some embodiments.

FIG. 1B illustrates a simplified perspective view showing an electronic system including a semiconductor device according to some embodiments.

FIGS. 1C and 1D illustrate simplified cross-sectional views showing a semiconductor package according to some embodiments.

FIG. 2A illustrates a plan view showing a semiconductor device according to some embodiments.

FIG. 2B illustrates an enlarged view showing section Q1 of FIG. 2A.

FIG. 2C illustrates a cross-sectional view taken along line A1-A1′ of FIG. 2B.

FIG. 2D illustrates a cross-sectional view taken along line B1-B1′ of FIG. 2B.

FIG. 2E illustrates a cross-sectional view taken along line C1-C1′ of FIG. 2B.

FIG. 2F illustrates a cross-sectional view taken along line D1-D1′ of FIG. 2B.

FIG. 2G illustrates a cross-sectional view taken along line E1-E1′ of FIG. 2B.

FIG. 2H illustrates an enlarged view showing section Q2 of FIG. 2D.

FIG. 2I illustrates an enlarged view showing section Q3 of FIG. 2E.

FIG. 2J illustrates an enlarged view showing section Q4 of FIG. 2E.

FIG. 2K illustrates an enlarged view showing section Q5 of FIG. 2J.

FIGS. 3A and 3B illustrate diagrams showing a method of manufacturing connection contact structures and parity contact structures according to FIGS. 2A to 2K.

FIGS. 4A, 4B, 5A, 5B, 5C, 5D, 6A, 6B, 6C, 6D, 7A, 7B, 7C, 7D, 8A, 8B, 8C, 8D, 9A, 9B, 9C, and 9D illustrate cross-sectional views showing a method of fabricating a semiconductor device according to FIGS. 2A to 2K.

FIG. 10A illustrates a plan view showing a semiconductor device according to some embodiments.

FIG. 10B illustrates a cross-sectional view taken along line A2-A2′ of FIG. 10A.

FIG. 10C illustrates a cross-sectional view taken along line B2-B2′ of FIG. 10A.

FIG. 10D illustrates a cross-sectional view taken along line C2-C2′ of FIG. 10A.

FIGS. 11A and 11B illustrate diagrams showing a method of manufacturing connection contact structures and parity contact structures according to FIGS. 10A to 10D.

FIGS. 12A, 12B, and 12C illustrate cross-sectional views showing a method of fabricating a semiconductor device according to FIGS. 10A to 10D.

FIG. 13A illustrates a plan view showing a semiconductor device according to some embodiments.

FIG. 13B illustrates an enlarged view showing section Q6 of FIG. 13A.

FIG. 14 illustrates an enlarged cross-sectional view showing a parity contact structure according to some embodiments.

FIG. 15 illustrates an enlarged cross-sectional view showing a parity contact structure according to some embodiments.

### DETAILED DESCRIPTION OF THE INVENTION

With reference to the accompanying drawings, the following will describe in detail semiconductor devices and electronic systems including the same according to some embodiments of the present inventive concepts.

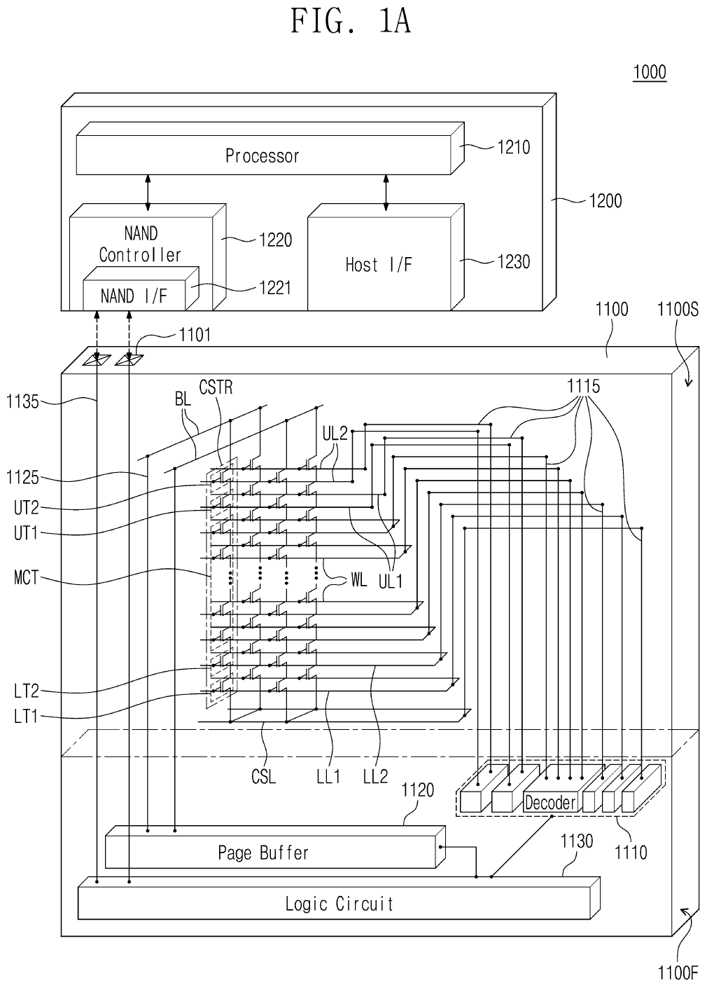

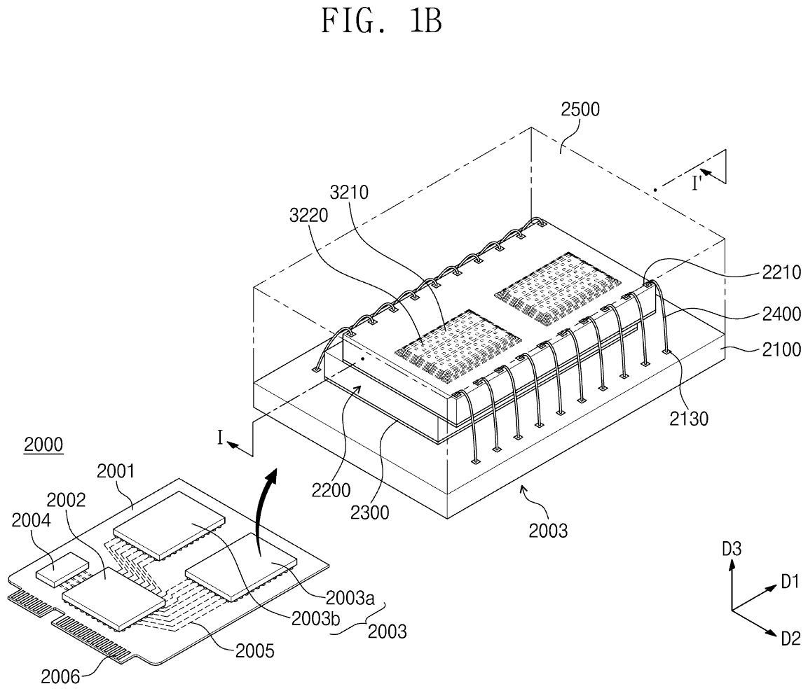

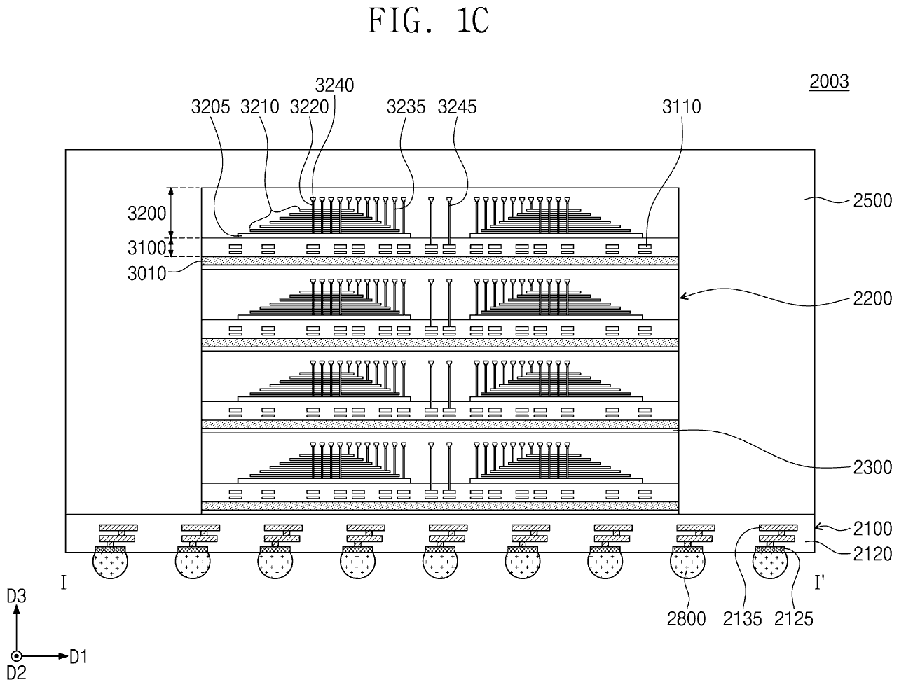

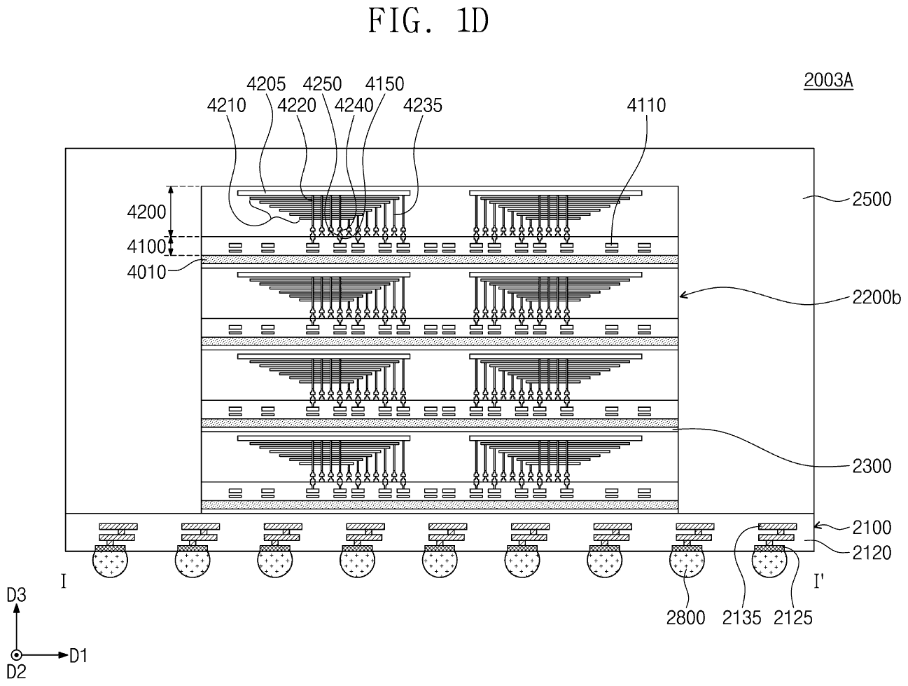

FIG. 1A illustrates a simplified block diagram showing an electronic system including a semiconductor device according to some embodiments.

Referring to FIG. 1A, an electronic system 1000 according to some embodiments may include a semiconductor device 1100 and a controller 1200 electrically connected to the semiconductor device 1100. The electronic system 1000 may be a storage device that includes a single or a plurality of semiconductor devices 1100, or may be an electronic device that includes the storage device, but not limited thereto. For example, the electronic system 1000 may be a solid state drive (SSD) device, a universal serial bus (USB), a computing system, a medical apparatus, or a communication apparatus, each of which includes a single or a plurality of semiconductor devices 1100.

The semiconductor device 1100 may be a nonvolatile memory device, such as a NAND Flash memory device. The semiconductor device 1100 may include a first structure 1100F and a second structure 1100S on the first structure 1100F. In some embodiments, the first structure 1100F may be disposed on a side of the second structure 1100S. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and memory cell transistors MCT disposed between the lower transistors LT1 and LT2 and the upper transistors UT1 and UT2. The number of the lower transistors LT1 and LT2 and of the upper transistors UT1 and UT2 may be variously changed in accordance with embodiments.

In some embodiments, the upper transistors UT1 and UT2 may include a string selection transistor, and the lower transistors LT1 and LT2 may include a ground selection transistor. The (first and second) gate lower lines LL1 and LL2 may be gate electrodes of the lower transistors LT1 and LT2, respectively. The word lines WL may be gate electrodes of the memory cell transistors MCT, and the (first and second) gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 that extend between the first structure 1100F and the second structure 1100S. The bit lines BL may be electrically connected to the page buffer 1120 through second connection lines 1125 that extend between the first structure 1100F and the second structure 1100S.

In the first structure 1100F, the decoder circuit 1110 and the page buffer 1120 may perform a control operation on at least one selection memory cell transistor among the plurality of memory cell transistors MCT. The logic circuit 1130 may control the decoder circuit 1110 and the page buffer 1120. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135 that extends between the first structure 1100F and the second structure 1100S.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 that includes the controller 1200. The processor 1210 may operate based on predetermined firmware, and may control the NAND controller 1220 to access the semiconductor device 1100. The NAND controller 1220 may include a NAND interface 1221 that processes communication with the semiconductor device 1100. The NAND interface 1221 may be used to transfer therethrough a control command to control the semiconductor device 1100, data intended to be written on the memory cell transistors MCT of the semiconductor device 1100, and/or data intended to be read from the memory cell transistors MCT of the semiconductor device 1100. The host interface 1230 may provide the electronic system 1000 with communication with an external host. When a control command is received through the host interface 1230 from an external host, the semiconductor device 1100 may be controlled by the processor 1210 in response to the control command. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

FIG. 1B illustrates a simplified perspective view showing an electronic system including a semiconductor device according to some embodiments.

Referring to FIG. 1B, an electronic system 2000 according to some example embodiments may include a main board 2001, a controller 2002 mounted on the main board 2001, at least one semiconductor package 2003, and a dynamic random access memory (DRAM) 2004. The semiconductor package 2003 and the DRAM 2004 may be (electrically) connected to the controller 2002 through wiring patterns 2005 formed on the main board 2001.

The main board 2001 may include a connector 2006 including a plurality of pins which will be (electrically) connected to an external host. The number and arrangement of the plurality of pins on the connector 2006 may be changed based on a communication interface between the electronic system 2000 and the external host. In some embodiments, the electronic system 2000 may communicate with the external host through one or more interfaces, for example, universal serial bus (USB), peripheral component interconnect express (PIC-Express), serial advanced technology attachment (SATA), and/or M-PHY for universal flash storage (UFS). In some embodiments, the electronic system 2000 may operate with power supplied through the connector 2006 from an external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor package 2003a and 2003b may include a package substrate 2100, semiconductor chips 2200 on the package substrate 2100, adhesion layers 2300 on lower surfaces (e.g., bottom surfaces) of the semiconductor chips 2200, connection structures 2400 that electrically connect the semiconductor chips 2200 to the package substrate 2100, and a molding layer 2500 that lies on the package substrate 2100 and on (e.g., covers) the semiconductor chips 2200 and the connection structures 2400.

The package substrate 2100 may be an integrated circuit board including package upper pads 2130. Each of the semiconductor chips 2200 may include one or more input/output pads 2210. The input/output pad 2210 may correspond to the input/output pad 1101 of FIG. 1A. Each of the semiconductor chips 2200 may include gate stack structures 3210 and memory channel structures 3220. Each of the semiconductor chips 2200 may include a semiconductor device which will be discussed below.

In some embodiments, the connection structures 2400 may be bonding wires that electrically connect the input/output pads 2210 to the package upper pads 2130. Therefore, in each of the first and second semiconductor packages 2003a and 2003b, the semiconductor chips 2200 may be electrically connected to each other in a wire bonding manner, and may be electrically connected to the package upper pads 2130 of the package substrate 2100. In some embodiments, in each of the first and second semiconductor packages 2003a and 2003b, the semiconductor chips 2200 may be electrically connected to each other using through-silicon vias (TSVs) instead of the connection structures 2400 (e.g., the bonding wires).

In some embodiments, the controller 2002 and the semiconductor chips 2200 may be included in one package. In some embodiments, the controller 2002 and the semiconductor chips 2200 may be mounted on a separate interposer substrate other than the main board 2001, and may be (electrically) connected to each other through connection lines provided in the interposer substrate.

FIGS. 1C and 1D illustrate simplified cross-sectional views showing a semiconductor package according to some embodiments. FIGS. 1C and 1D each depicts an example embodiment of the semiconductor package 2003 shown in FIG. 1B, conceptually showing a section taken along line I-I′ of the semiconductor package 2003 shown in FIG. 1B.

Referring to FIG. 1C, a printed circuit board may be used as the package substrate 2100 of the semiconductor package 2003. The package substrate 2100 may include a package substrate body 2120, package upper pads (see 2130 of FIG. 1B) disposed on an upper surface (e.g., a top surface) of the package substrate body 2120, lower pads 2125 disposed or exposed on a lower surface (e.g., a bottom surface) of the package substrate body 2120, and internal lines 2135 that lie in the package substrate body 2120 and electrically connect the upper pads 2130 to the lower pads 2125. The upper pads 2130 may be electrically connected to connection structures (see 2400 of FIG. 1B). The lower pads 2125 may be (electrically) connected through conductive connectors 2800 to the wiring patterns 2005 on the main board 2001 of the electronic system 2000, as shown in FIG. 1B.

Each of the semiconductor chips 2200 may include a semiconductor substrate 3010, and may also include a first structure 3100 and a second structure 3200 that are sequentially stacked on the semiconductor substrate 3010. The first structure 3100 may include a peripheral circuit region including peripheral wiring lines 3110. The second structure 3200 may include a common source line 3205, a gate stack structure 3210 on the common source line 3205, memory channel structures 3220 that extend in (e.g., penetrate) the gate stack structure 3210, bit lines 3240 electrically connected to the memory channel structures 3220, and gate contact plugs 3235 electrically connected to corresponding word lines (see WL of FIG. 1A) of the gate stack structure 3210.

Each of the semiconductor chips 2200 may include through wiring lines 3245 that are electrically connected to the peripheral wiring lines 3110 of the first structure 3100 and that extend into the second structure 3200. The through wiring line 3245 may be disposed outside (may be spaced apart from) the gate stack structure 3210. In some embodiments, the through wiring line 3245 may extend in (e.g., penetrate) the gate stack structure 3210. Each of the semiconductor chips 2200 may further include an input/output pad (see 2210 of FIG. 1B).

Referring to FIG. 1D, in a semiconductor package 2003A, each of semiconductor chips 2200b may include a semiconductor substrate 4010, a first structure 4100 on the semiconductor substrate 4010, and a second structure 4200 provided on and/or wafer-bonded to the first structure 4100. As used herein, the term “and/or” includes any and all combinations of one or more of the associated listed items.

The first structure 4100 may include a peripheral circuit region including a peripheral wiring line 4110 and first bonding structures 4150. The second structure 4200 may include a common source line 4205, a gate stack structure 4210 between the common source line 4205 and the first structure 4100, memory channel structures 4220 that extend in (e.g., penetrate) the gate stack structure 4210, bit lines 4240 electrically connected to the memory channel structures 4220, gate contact plugs 4235 electrically connected to corresponding word lines (see WL of FIG. 1A) of the gate stack structure 4210, and second bonding structures 4250. For example, the second bonding structures 4250 may be electrically connected to corresponding memory channel structures 4220 through the bit lines 4240 electrically connected to the memory channel structures 4220. The first bonding structures 4150 of the first structure 4100 may be electrically connected (e.g., bonded) to the second bonding structures 4250 of the second structure 4200. The first and second bonding structures 4150 and 4250 may have their bonding portions formed of, for example, copper (Cu). Each of the semiconductor chips 2200b may further include an input/output pad (see 2210 of FIG. 1B).

The semiconductor chips 2200 of FIG. 1C or the semiconductor chips 2200b of FIG. 1D may be electrically connected to each other through the connection structures (see 2400 of FIG. 1B) shaped like bonding wires. In some embodiments, semiconductor chips in one semiconductor package, such as the semiconductor chips 2200 of FIG. 1C or the semiconductor chips 2200b of FIG. 1D, may be electrically connected to each other through connection structures including through electrodes (e.g., TSVs).

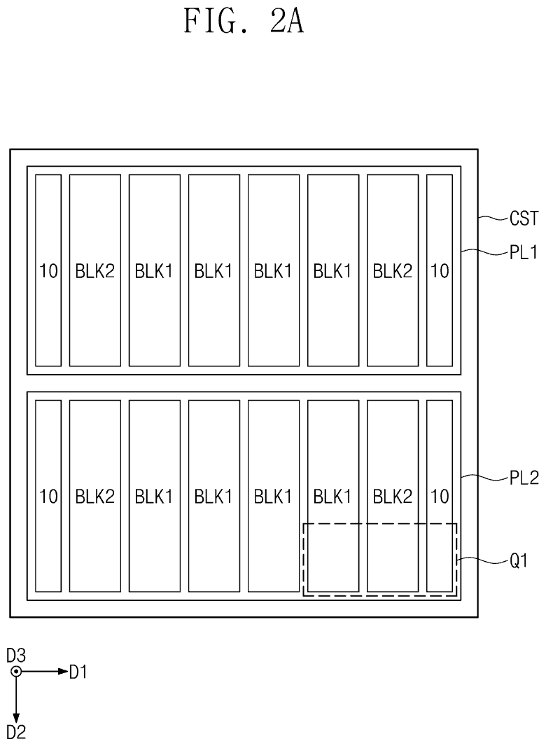

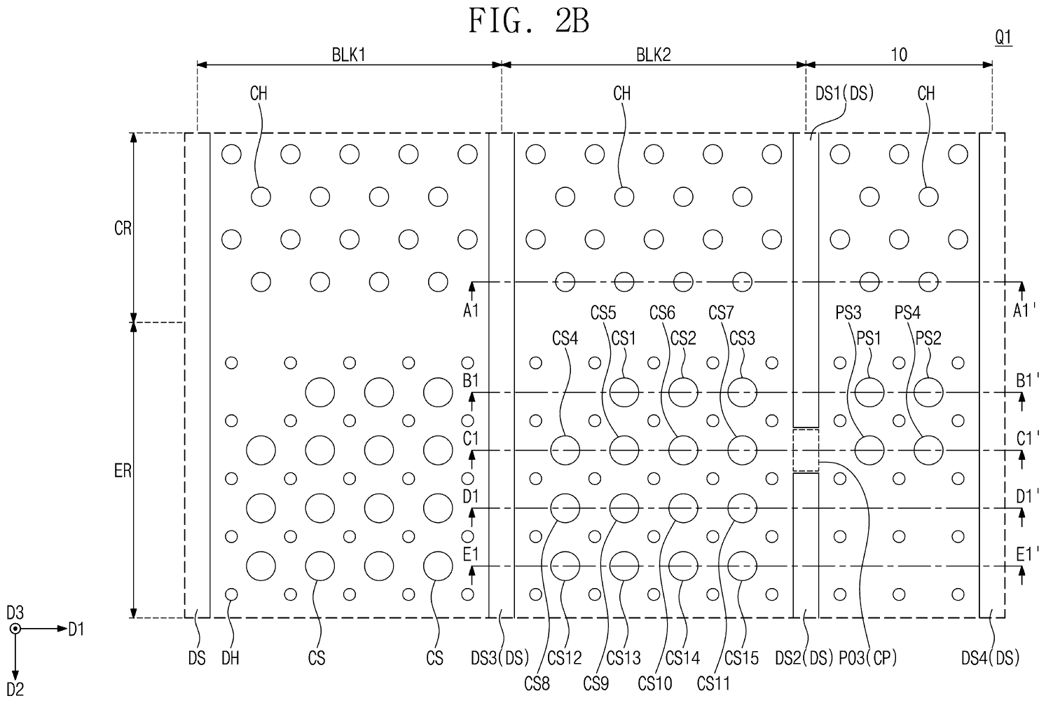

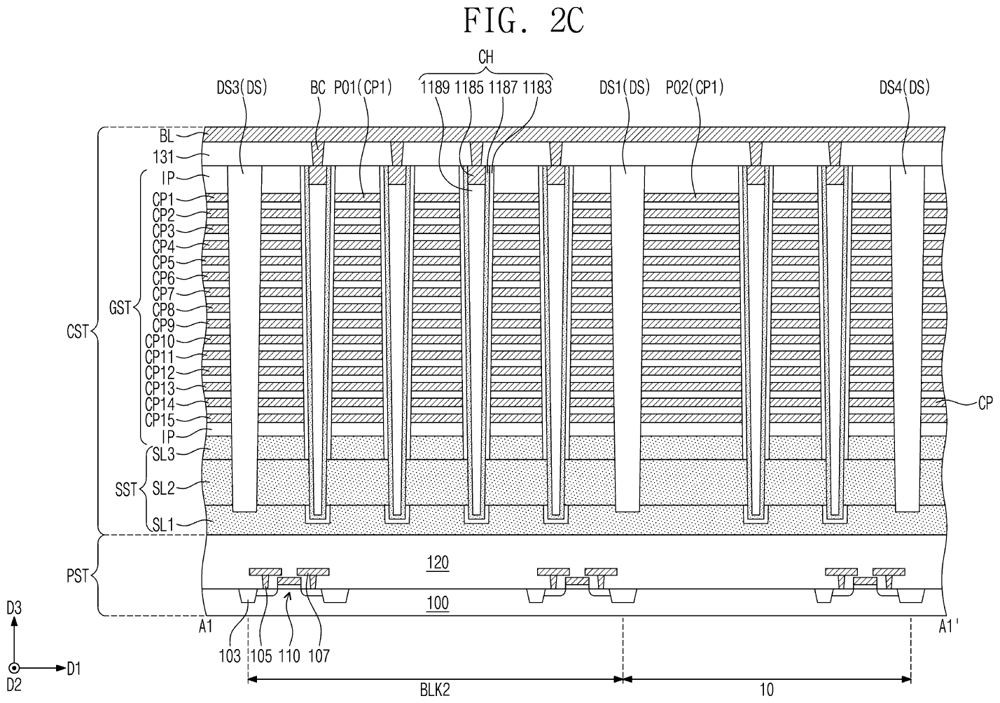

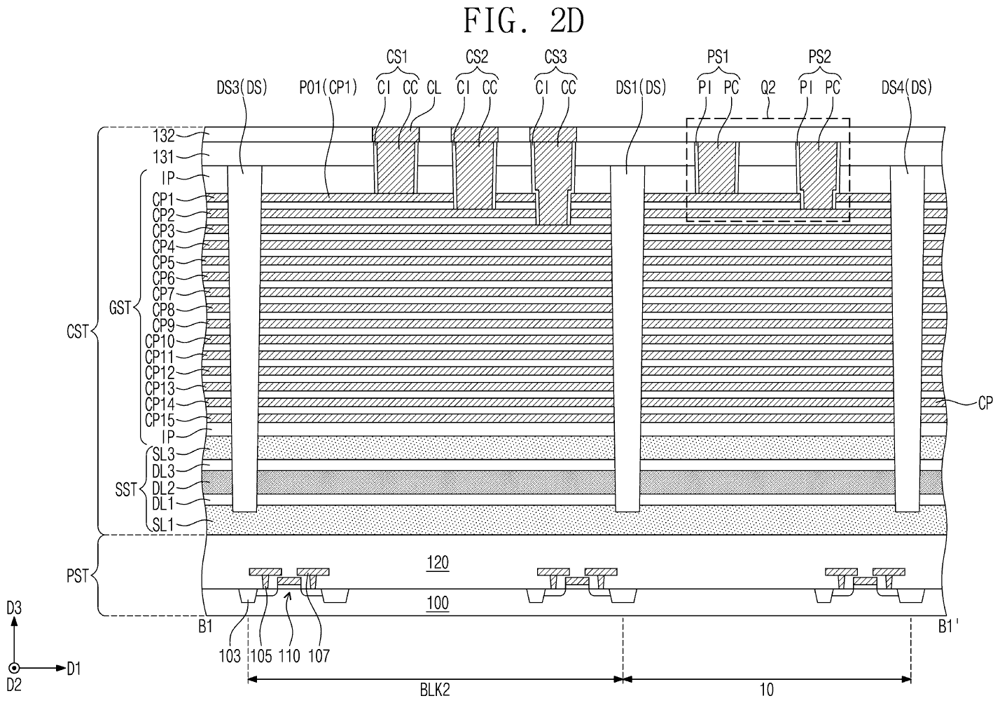

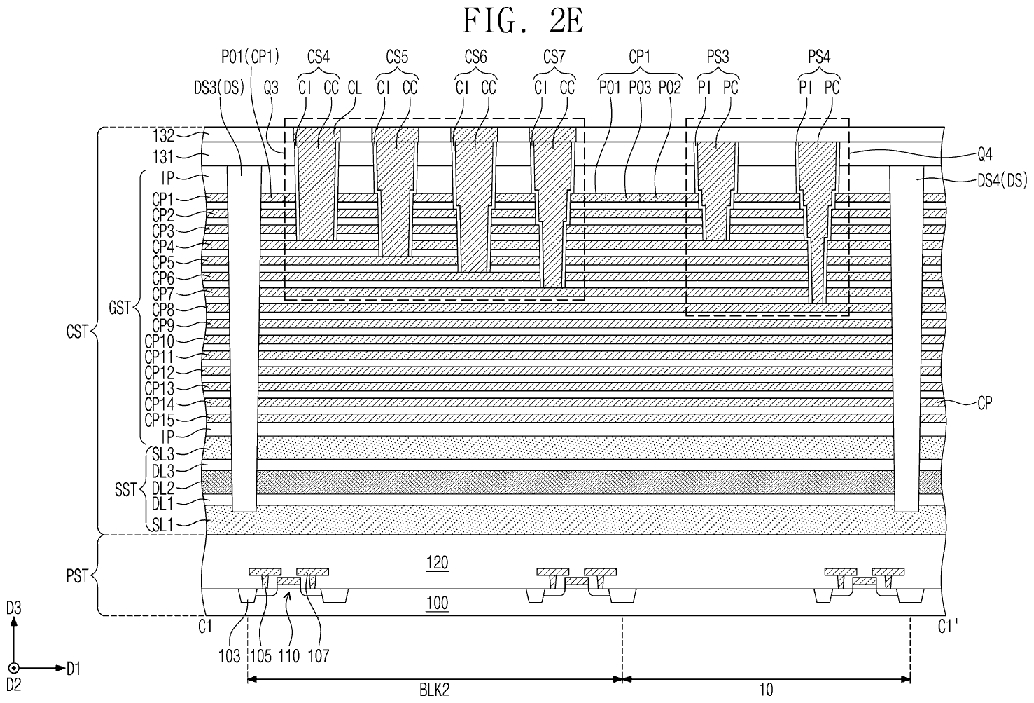

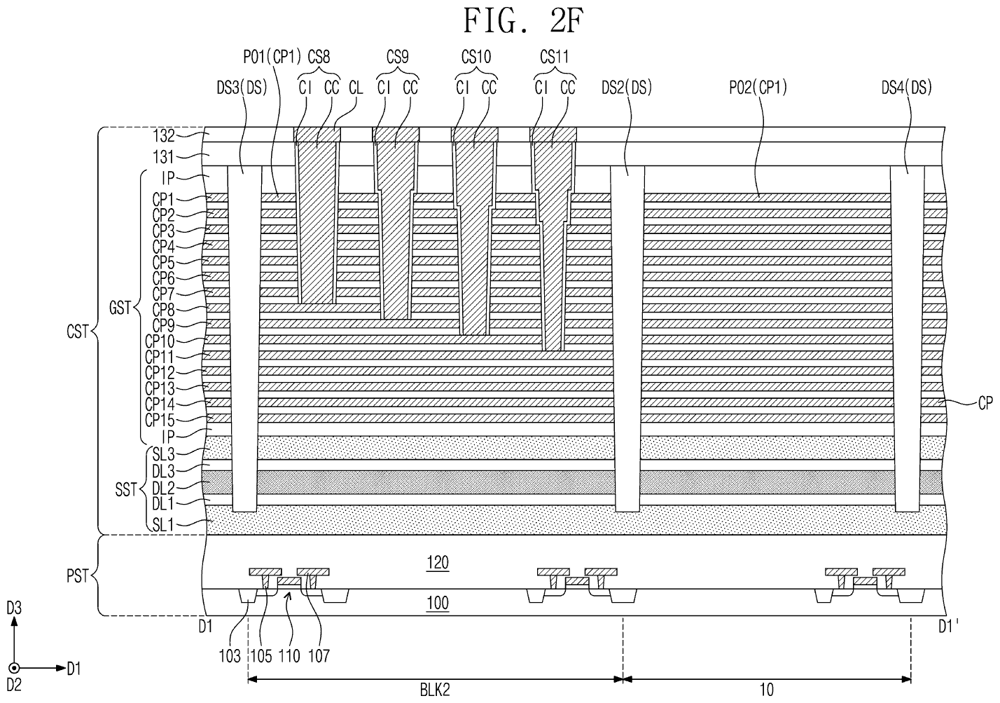

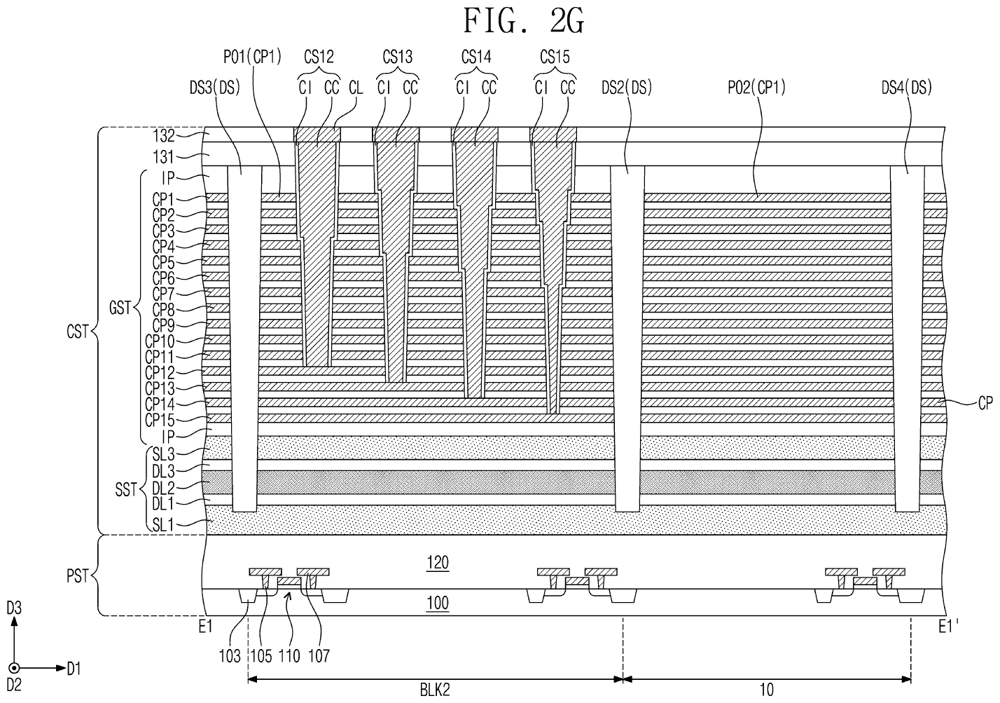

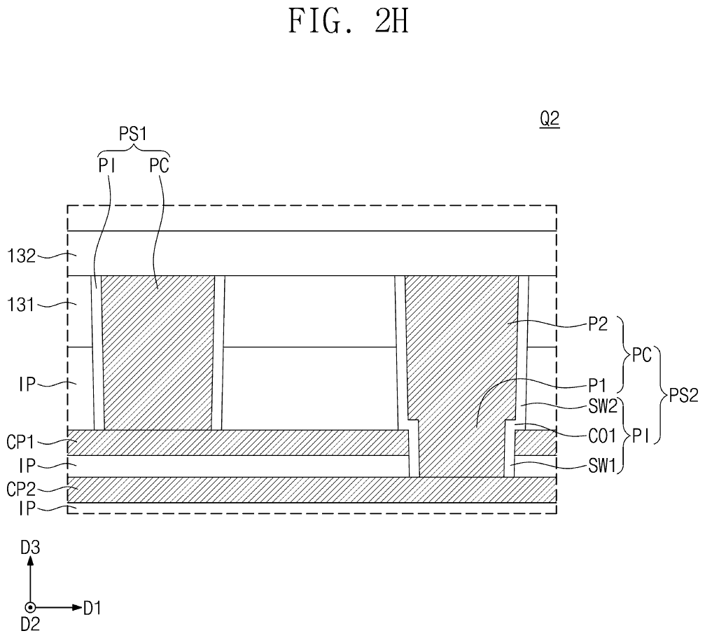

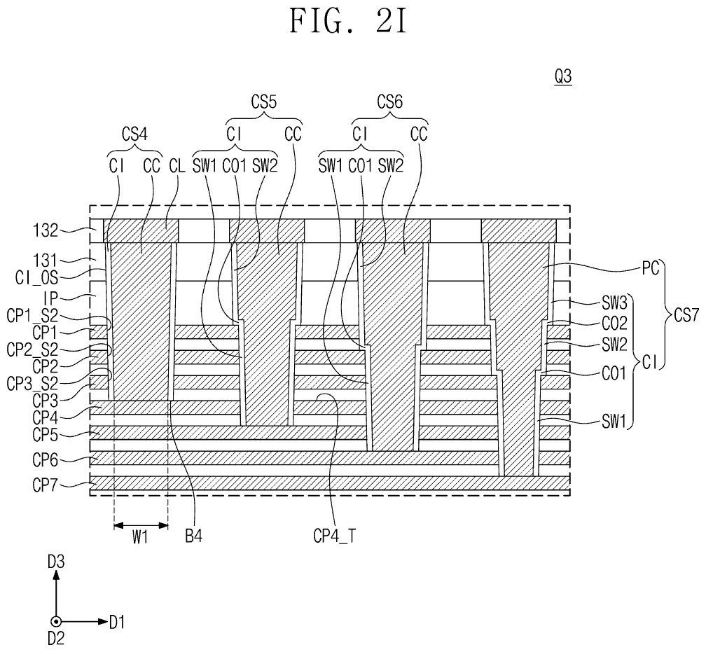

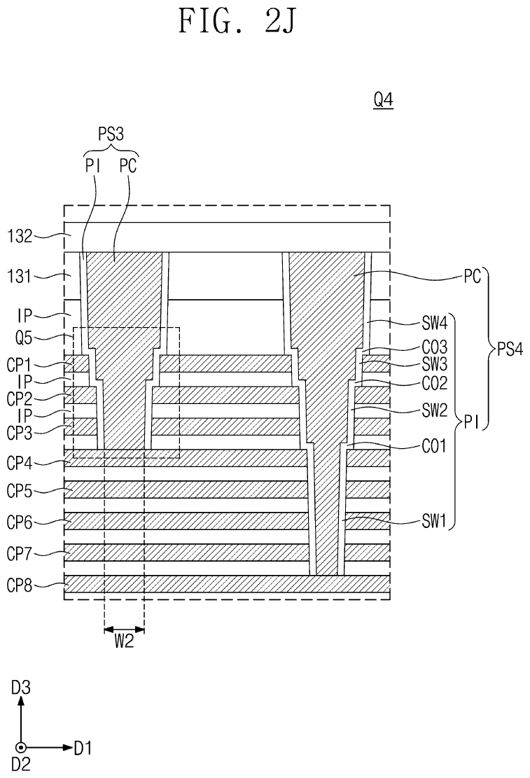

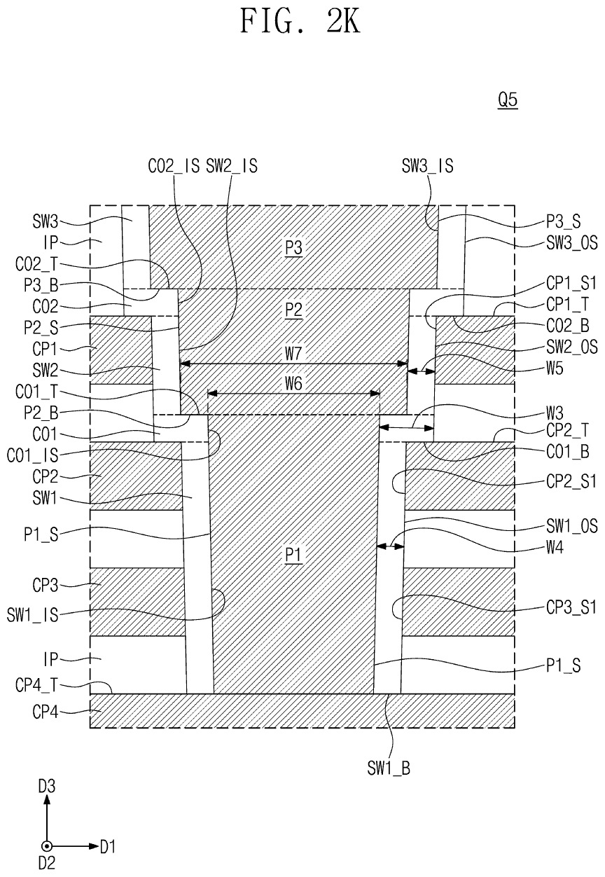

FIG. 2A illustrates a plan view showing a semiconductor device according to some embodiments. FIG. 2B illustrates an enlarged view showing section Q1 of FIG. 2A. FIG. 2C illustrates a cross-sectional view taken along line A1-A1′ of FIG. 2B. FIG. 2D illustrates a cross-sectional view taken along line B1-B1′ of FIG. 2B. FIG. 2E illustrates a cross-sectional view taken along line C1-C1′ of FIG. 2B. FIG. 2F illustrates a cross-sectional view taken along line D1-D1′ of FIG. 2B. FIG. 2G illustrates a cross-sectional view taken along line E1-E1′ of FIG. 2B. FIG. 2H illustrates an enlarged view showing section Q2 of FIG. 2D. FIG. 2I illustrates an enlarged view showing section Q3 of FIG. 2E. FIG. 2J illustrates an enlarged view showing section Q4 of FIG. 2E. FIG. 2K illustrates an enlarged view showing section Q5 of FIG. 2J.

Referring to FIG. 2A, a memory cell structure CST of a semiconductor device may include a first plane PL1 and a second plane PL2. The first plane PL1 and the second plane PL2 may be distinguished from a planar perspective defined by a first direction D1 and a second direction D2. The first direction D1 and the second direction D2 may intersect each other. For example, the first direction D1 and the second direction D2 may be horizontal directions that are orthogonal to each other. The horizontal directions (e.g., the first direction D1 and the second direction D2) may be parallel with an upper surface and/or a lower surface of a substrate, such as a substrate 100 (See 100 in FIGS. 2B, 2C, 2D, 2E, 2F, and 2G). The first plane PL1 and the second plane PL2 may be spaced apart from each other in the second direction D2. The number of the planes PL1 and PL2 may not be limited to that shown. In some embodiments, the number of the planes PL1 and PL2 may be three or more.

Each of the first plane PL1 and the second plane PL2 may include first blocks BLK1, second blocks BLK2, and parity regions 10. The parity regions 10 of the first plane PL1 may be spaced apart from each other in the first direction D1. The first and second blocks BLK1 and BLK2 of the first plane PL1 may be disposed between the parity regions 10 of the first plane PL1 (in the first direction D1). The second blocks BLK2 of the first plane PL1 may be spaced apart from each other in the first direction D1. The first blocks BLK1 of the first plane PL1 may be disposed between the second blocks BLK2 of the first plane PL1 (in the first direction D1). The parity region 10 may be (electrically) connected to the second block BLK2. In some embodiments, the first blocks BLK1 may be cell blocks, and the second blocks BLK2 may be dummy blocks. In some embodiments, the first and second blocks BLK1 and BLK2 may be cell blocks. In some embodiments, each of the planes PL1 and PL2 may include one parity region 10 and one second block BLK2.

Referring to FIGS. 2B, 2C, 2D, 2E, 2F, and 2G, the semiconductor device may include a peripheral circuit structure PST and a memory cell structure CST on the peripheral circuit structure PST.

The peripheral circuit structure PST may include a substrate 100. The substrate 100 may be a semiconductor substrate, a dielectric substrate, a silicon-on-insulator substrate, or a germanium-on-insulator substrate, but not limited thereto. The peripheral circuit structure PST may include a peripheral circuit dielectric layer 120 on the substrate 100. The peripheral circuit dielectric layer 120 may include a dielectric material. In some embodiments, the peripheral circuit dielectric layer 120 may be a multiple dielectric layer including a plurality of dielectric layers.

The substrate 100 may be provided with device isolation layers 103 therein. The device isolation layers 103 may include a dielectric material. The peripheral circuit structure PST may further include transistors 110. The transistors 110 may be provided between (in) the substrate 100 and the peripheral circuit dielectric layer 120. The transistor 110 may include source/drain regions, a gate dielectric layer, and a gate electrode.

The peripheral circuit structure PST may further include peripheral contacts 105 and peripheral conductive lines 107. The peripheral contact 105 may be (electrically) connected to the transistor 110. The peripheral conductive line 107 may be (electrically) connected to the peripheral contact 105. The peripheral contact 105 and the peripheral conductive line 107 may include a conductive material.

The memory cell structure CST may include a source structure SST, a gate stack structure GST, memory channel structures CH, a first cover dielectric layer 131, a second cover dielectric layer 132, separation structures DS, connection contact structures CS, parity contact structures PS (e.g., PS1, PS2, PS3, and PS4), bit-line contacts BC, bit lines BL, dummy structures DH, and conductive lines CL.

The source structure SST may include a cell region CR and an extension region ER. The cell region CR and the extension region ER may be distinguished from a planar perspective defined by a first direction D1 and a second direction D2.

The source structure SST may include a first source layer SL1 on the peripheral circuit structure PST, a second source layer SL2 on the first source layer SL1, a first dummy layer DL1, a second dummy layer DL2, and a third dummy layer DL3 on the first source layer SL1, and a third source layer SL3 on the second source layer SL2 and the third dummy layer DL3.

The first, second, and third source layers SL1, SL2, and SL3 may include a conductive material. For example, the first, second, and third source layers SL1, SL2, and SL3 may include polysilicon. The second source layer SL2 may be disposed on the cell region CR. The second source layer SL2 may be a common source line.

The first dummy layer DL1, the second dummy layer DL2, and the third dummy layer DL3 may be sequentially provided along a third direction D3 on the first source layer SL1. The first, second, and third dummy layers DL1, DL2, and DL3 may be disposed on the extension region ER. The first, second, and third dummy layers DL1, DL2, and DL3 may be located at the same level as that of the second source layer SL2. The level may be a relative location (e.g., distance) from the lower surface of the substrate 100 in the third direction D3. A farther distance from the lower surface of the substrate 100 may be a higher level. A closer distance from the lower surface of the substrate 100 may be a lower level. The first, second, and third dummy layer DL1, DL2, and DL3 may include a dielectric material. In some embodiments, the first and third dummy layers DL1 and DL3 may include the same dielectric material, and the second dummy layer DL2 may include a dielectric material different from that of the first and third dummy layers DL1 and DL3. For example, the second dummy layer DL2 may include nitride, and the first and third dummy layers DL1 and DL3 may include oxide.

The gate stack structure GST may be provided on the source structure SST. In some embodiments, the number of the gate stack structure GST may be two or more.

The gate stack structure GST may include dielectric patterns IP and conductive patterns CP that are alternately stacked along the third direction D3. The third direction D3 may intersect the first direction D1 and the second direction D2. For example, the third direction D3 may be a vertical direction perpendicular to the first direction D1 and the second direction D2. The third direction D3 may be perpendicular to an upper surface and/or a lower surface of a substrate, such as the substrate 100. The third direction D3 may be perpendicular to an upper surface and/or a lower surface of each of the conductive patterns CP. The first and second directions D1 and D2 may be parallel with the upper surface and/or the lower surface of each of the conductive patterns CP.

The dielectric patterns IP may include a dielectric material. For example, the dielectric patterns IP may include oxide. The conductive patterns CP may include a conductive material. For example, the conductive patterns CP may include tungsten.

The memory channel structures CH may extend in the third direction D3 to penetrate the conductive patterns CP and the dielectric patterns IP of the gate stack structure GST. The memory channel structures CH may extend in (e.g., penetrate) the third source layer SL3 and the second source layer SL2 (in the third direction D3). Each of the memory channel structures CH may include a dielectric capping layer 1189, a channel layer 1187 that extends around (e.g., surrounds) (side surfaces of) the dielectric capping layer 1189, and a memory layer 1183 that extends around (e.g., surrounds) (side surfaces of) the channel layer 1187. The memory channel structures CH may be disposed on the cell region CR.

The dielectric capping layer 1189 may include a dielectric material. For example, the dielectric capping layer 1189 may include oxide. The channel layer 1187 may include a conductive material. For example, the channel layer 1187 may include polysilicon. The channel layer 1187 may be electrically connected to the second source layer SL2. The second source layer SL2 may penetrate the memory layer 1183 to come into connection (e.g., contact) with the channel layer 1187.

The memory layer 1183 may store data. In some embodiments, the memory layer 1183 may include a tunnel dielectric layer that extends around (e.g., surrounds) (side surfaces of) the channel layer 1187, a data storage layer that extends around (e.g., surrounds) (side surfaces of) the tunnel dielectric layer, and a blocking layer that extends around (e.g., surrounds) (side surfaces of) the data storage layer. The tunnel dielectric layer and the blocking layer may include, for example, oxide. The data storage layer may include, for example, nitride.

Each of the memory channel structures CH may further include a bit-line pad 1185 provided on the channel layer 1187 (and/or on the dielectric capping layer 1189). The bit-line pad 1185 may include a conductive material. For example, the bit-line pad 1185 may include polysilicon or metal.

The dummy structures DH may extend in the third direction D3 to penetrate the conductive patterns CP and the dielectric patterns IP of the gate stack structure GST. The dummy structures DH may be disposed on the extension region ER. The dummy structures DH may include a dielectric material. In some embodiments, the dummy structures DH may have a similar structure as that of the memory channel structure CH. The dummy structure DH may be adjacent to the connection contact structure CS or the parity contact structure PS1, PS2, PS3, and PS4.

The first cover dielectric layer 131 may be provided on the gate stack structure GST and the memory channel structures CH. The first cover dielectric layer 131 may include a dielectric material. The second cover dielectric layer 132 may be provided on the first cover dielectric layer 131. The second cover dielectric layer 132 may include a dielectric material.

The separation structures DS may extend in (e.g., penetrate) the gate stack structure GST (in the third direction D3). The separation structures DS may extend in the second direction D2. The separation structure DS may include a dielectric material. In some embodiments, the separation structure DS may further include a source contact electrically connected to the source structure SST.

The bit-line contact BC may be (electrically) connected to the memory channel structure CH. The bit-line contact BC may penetrate the first cover dielectric layer 131. The bit line BL may be provided on the bit-line contact BC. The bit line BL may be provided in the second cover dielectric layer 132. The conductive line CL may be provided on the connection contact structure CS. The conductive line CL may be provided in the second cover dielectric layer 132. The bit-line contact BC, the bit line BL, and the conductive line CL may include a conductive material.

The separation structures DS may include a first separation structure DS1 and a second separation structure DS2 between the second block BLK2 and the parity region 10. The first separation structure DS1 and the second separation structure DS2 may be spaced apart from each other in the second direction D2.

The connection contact structures CS may be disposed on the first block BLK1 and the second block BLK2. The parity contact structures PS1, PS2, PS3, and PS4 may be disposed on the parity region 10. The separation structures DS may further include a third separation structure DS3 and a fourth separation structure DS4 adjacent to the first separation structure DS1 and the second separation structure DS2. The third separation structure DS3 may be provided between the second block BLK2 and the first block BLK1 (in the first direction D1). The parity region 10 may be provided between the first and second separation structures DS1 and DS2 and the fourth separation structure DS4 (in the first direction D1). For example, the second block BLK2 may be between the first block BLK1 and the parity region 10 (in the first direction D1). The first and second separation structures DS1 and DS2 may be between the second block BLK2 and the parity region 10 (in the first direction D1).

The connection contact structures CS of the second block BLK2 may include a first connection contact structure CS1, a second connection contact structure CS2, a third connection contact structure CS3, a fourth connection contact structure CS4, a fifth connection contact structure CS5, a sixth connection contact structure CS6, a seventh connection contact structure CS7, an eighth connection contact structure CS8, a ninth connection contact structure CS9, a tenth connection contact structure CS10, an eleventh connection contact structure CS11, a twelfth connection contact structure CS12, a thirteenth connection contact structure CS13, a fourteenth connection contact structure CS14, and a fifteenth connection contact structure CS15. The first to fifteenth connection contact structures CS1 to CS15 may be disposed between the first and second separation structures DS1 and DS2 and the third separation structure DS3 (in the first direction D1). The first to fifth connection contact structures CS1 to CS15 may extend through at least a portion of the gate stack structure GST. The first to fifteenth connection contact structures CS1 to CS15 may extend in the third direction D3. However, the number of the connection contact structures is not limited to that shown above.

The parity contact structures PS1 to PS4 of the parity region 10 may include a first parity contact structure PS1, a second parity contact structure PS2, a third parity contact structure PS3, and a fourth parity contact structure PS4. The first to fourth parity contact structures PS1 to PS4 may be disposed between the fourth separation structure DS4 and the first and second separation structures DS1 and DS2 (in the first direction D1). The first to fourth parity contact structures PS1 to PS4 may extend through at least a portion of the gate stack structure GST. The first to fourth parity contact structures PS1 to PS4 may extend in the third direction D3. However, the number of the parity contact structures is not limited to that shown above.

The conductive patterns CP may include a first conductive pattern CP1, a second conductive pattern CP2, a third conductive pattern CP3, a fourth conductive pattern CP4, a fifth conductive pattern CP5, a sixth conductive pattern CP6, a seventh conductive pattern CP7, an eighth conductive pattern CP8, a ninth conductive pattern CP9, a tenth conductive pattern CP10, an eleventh conductive pattern CP11, a twelfth conductive pattern CP12, a thirteenth conductive pattern CP13, a fourteenth conductive pattern CP14, and a fifteenth conductive pattern CP15. However, the number of the conductive patterns CP is not limited to that shown above.

The first to fifteenth conductive patterns CP1 to CP15 may be disposed on the second block BLK2 and the parity region 10. Each of the first to fifteenth conductive patterns CP1 to CP15 may include a portion disposed on the second block BLK2 and a portion disposed on the parity region 10. The first to fifteenth conductive patterns CP1 to CP15 may be sequentially arranged along a direction opposite to the third direction D3. For example, the first conductive pattern CP1 may be the highest one of the conductive patterns CP, and the fifteenth conductive pattern CP15 may be the lowest one of the conductive patterns CP. The first to fifteenth conductive patterns CP1 to CP15 may be spaced apart from each other in the third direction D3.

The first to fifteenth connection contact structures CS1 to CS15 may be correspondingly electrically connected to (e.g., correspondingly in contact with) the first to fifteenth conductive patterns CP1 to CP15. For example, the fourth connection contact structure CS4 may be electrically connected to (e.g., in contact with) the fourth conductive pattern CP4, and the second connection contact structure CS2 may be electrically connected to (e.g., in contact with) the second conductive pattern CP2. The fourth connection contact structure CS4 may penetrate through the first, second, and third conductive patterns CP1, CP2, and CP3. The first, second, and third conductive patterns CP1, CP2, and CP3 may extend around (e.g., surround) (side surfaces of) the fourth connection contact structure CS4.

The first parity contact structure PS1 may be electrically connected to (e.g., in contact with) the first conductive pattern CP1. The second parity contact structure PS2 may be electrically connected to (e.g., in contact with) the second conductive pattern CP2. The third parity contact structure PS3 may be electrically connected to (e.g., in contact with) the fourth conductive pattern CP4. The fourth parity contact structure PS4 may be electrically connected to (e.g., in contact with) the eighth conductive pattern CP8. The third parity contact structure PS3 may penetrate the first, second, and third conductive patterns CP1, CP2, and CP3. The first, second, and third conductive patterns CP1, CP2, and CP3 may extend around (e.g., surround) (side surfaces of) the third parity contact structure PS3.

Each of the first to fifteenth connection contact structures CS1 to CS15 may include a connection contact CC. The connection contact CC may be in contact with the conductive pattern CP. For example, the connection contact CC of the fourth connection contact structure CS4 may be in contact with the fourth conductive pattern CP4. The connection contact CC may include a conductive material.

The connection contacts CC of the first to fifteenth connection contact structures CS1 to CS15 may have different lengths in the third direction D3. For example, a length in the third direction D3 of the connection contact CC of the fourth connection contact structure CS4 may be less than a length in the third direction D3 of the connection contact CC of the seventh connection contact structure CS7.

Each of the first to fifteenth connection contact structures CS1 to CS15 may include a connection contact dielectric layer CI that extends around (e.g., surrounds) (side surfaces of) the connection contact CC. The connection contact dielectric layer CI may include a dielectric material.

Each of the first to fourth parity contact structures PS1 to PS4 may include a parity contact PC. The parity contact PC may be in contact with the conductive pattern CP. The parity contact PC may include a conductive material.

Each of the first to fourth parity contact structures PS1 to PS4 may include a parity contact dielectric layer PI that extends around (e.g., surrounds) (side surfaces of) the parity contact PC. The parity contact dielectric layer PI may include a dielectric material.

The number of the conductive patterns CP1 to CP15 in contact with each of the third and fourth parity contact structures PS3 and PS4 may be a multiple of four. In some embodiments, the number of conductive patterns CP1 to CP15 in contact with a connection contact structure CS may be a multiple of four. The third parity contact structure PS3 may be in contact with the first to fourth conductive patterns CP1 to CP4. The third parity contact structure PS3 may be in contact with sidewalls of the first to third conductive patterns CP1 to CP3 and an upper surface (e.g., a top surface) of the fourth conductive pattern CP4. The fourth parity contact structure PS4 may be in contact with the first to eighth conductive patterns CP1 to CP8. The fourth parity contact structure PS4 may be in contact with sidewalls of the first to seventh conductive patterns CP1 to CP7 and an upper surface (e.g., a top surface) of the eighth conductive pattern CP8.

In some embodiments, the second block BLK2 and the parity region 10 of the semiconductor device may include (16×N)−1 conductive patterns, (16×N)−1 connection contact structures, and N+3 parity contact structures (where, N is 1, 2, 4, 8, 16, . . . ).

Each of the first to fifteenth conductive patterns CP1 to CP15 may include a first conductive part PO1, a second conductive part PO2, and a third conductive part PO3. The first conductive part PO1 may be disposed on the second block BLK2. The second conductive part PO2 may be disposed on the parity region 10. The third conductive part PO3 may be disposed between the second block BLK2 and the parity region 10 (in the first direction D1). The third conductive part PO3 may be disposed between the first and second conductive parts PO1 and PO2 (in the first direction D1). The third conductive part PO3 may connect the first and second conductive parts PO1 and PO2 to each other. The third conductive part PO3 may be in contact with the first and second conductive parts PO1 and PO2.

The first conductive part PO1 may be disposed between the third separation structure DS3 and the first and second separation structures DS1 and DS2 (in the first direction D1). The second conductive part PO2 may be disposed between the fourth separation structure DS4 and the first and second separation structures DS1 and DS2 (in the first direction D1). The third conductive part PO3 may be disposed between the first and second separation structures DS1 and DS2 (in the second direction D2). A width in the second direction D2 of the third conductive part PO3 may be less than a width in the second direction D2 of each of the first and second conductive parts PO1 and PO2.

The first separation structure DS1 and the second separation structure DS2 may be disposed between the first to fifteenth connection contact structures CS1 to CS15 and the first to fourth parity contact structures PS1 to PS4 (in the first direction D1).

The connection contact CC may be in contact with the first conductive part PO1. The parity contact PC may be in contact with the second conductive part PO2. The connection contact CC and the parity contact PC may be electrically connected to each other through the first conductive part PO1, the third conductive part PO3, and the second conductive part PO2.

Referring to FIG. 2K, the parity contact dielectric layer PI of the third parity contact structure PS3 may include a first sidewall part SW1, a first connection part CO1, a second sidewall part SW2, a second connection part CO2, and a third sidewall part SW3. A lower surface (e.g., a bottom surface) SW1_B of the first sidewall part SW1 may be in contact with an upper surface (e.g., a top surface) CP4_T of the fourth conductive pattern CP4. An outer sidewall part SW1_OS of the first sidewall part SW1 may be in contact with a first sidewall CP3_S1 of the third conductive pattern CP3 and a first sidewall CP2_S1 of the second conductive pattern CP2.

The first connection part CO1 may connect the first sidewall part SW1 and the second sidewall part SW2 to each other. A lower surface (e.g., a bottom surface) CO1_B of the first connection part CO1 may be in contact with an upper surface (e.g., a top surface) CP2_T of the second conductive pattern CP2. A width W3 in the first direction D1 of the first connection part CO1 may be greater than a width W4 in the first direction D1 of the first sidewall part SW1 and a width W5 in the first direction D1 of the second sidewall part SW2.

An outer sidewall SW2_OS of the second sidewall part SW2 may be in contact with a first sidewall CP1_S1 of the first conductive pattern CP1. The second connection part CO2 may connect the second sidewall part SW2 and the third sidewall part SW3 to each other. A lower surface (e.g., a bottom surface) CO2_B of the second connection part CO2 may be in contact with an upper surface (e.g., a top surface) CP1_T of the first conductive pattern CP1. An outer sidewall SW3_OS of the third sidewall part SW3 may be in contact with a sidewall of the dielectric pattern IP.

The parity contact PC of the third parity contact structure PS3 may include a first part P1, a second part P2 on the first part P1, and a third part P3 on the second part P2. Each of the first, second, and third parts P1, P2, and P3 may have a width in the first direction D1, which width decreases as a level is lowered. A maximum width W6 in the first direction D1 of the first part P1 may be less than a minimum width W7 in the first direction D1 of the second part P2. A maximum width in the first direction D1 of the second part P2 may be less than a minimum width in the first direction D1 of the third part P3.

A sidewall P1_S of the first part P1 may be in contact with an inner sidewall SW1_IS of the first sidewall part SW1 and an inner sidewall CO1_IS of the first connection part CO1. A lower surface (e.g., a bottom surface) P2_B of the second part P2 may be in contact with an upper surface (e.g., a top surface) CO1_T of the first connection part CO1. A sidewall P2_S of the second part P2 may be in contact with an inner sidewall SW2_IS of the second sidewall part SW2 and an inner sidewall CO2_IS of the second connection part CO2. A lower surface (e.g., bottom surface) P2_B of the second part P2 may connect the sidewall P1_S of the first part P1 to the sidewall P2_S of the second part P2. A lower surface (e.g., a bottom surface) P3_B of the third part P3 may be in contact with an upper surface (e.g., a top surface) CO2_T of the second connection part CO2. A sidewall P3_S of the third part P3 may be in contact with an inner sidewall SW3_IS of the third sidewall part SW3. For example, the first sidewall part SW1 and the first connection part CO1 may extend around (e.g., surround) (the sidewall P1_S of) the first part P1. The second sidewall part SW2 and the second connection part CO2 may extend around (e.g., surround) (the sidewall P2_S of) the second part P2. The third sidewall part SW3 may extend around (e.g., surround) (the sidewall P3_S of) the third part P3.

Referring to FIGS. 2H, 2I, 2J, and 2K, in some embodiments, a maximum width in the first direction D1 of the connection contact CC included in the fourth connection contact structure CS4 may be the same as a maximum width in the first direction D1 of the third part P3 of the parity contact PC included in the third parity contact structure PS3.

A lower surface (e.g., a bottom surface) B4 of the connection contact dielectric layer CI of the fourth connection contact structure CS4 may be in contact with an upper surface (e.g., a top surface) CP4_T of the fourth conductive pattern CP4. An outer sidewall CI_OS of the connection contact dielectric layer CI of the fourth connection contact structure CS4 may be in contact with a second sidewall CP3_S2 of the third conductive pattern CP3, a second sidewall CP2_S2 of the second conductive pattern CP2, and a second sidewall CP1_S2 of the first conductive pattern CP1.

The parity contact dielectric layer PI of the fourth parity contact structure PS4 may include first, second, third, and fourth sidewall parts SW1, SW2, SW3, and SW4 and first, second, and third connection parts CO1, CO2, and CO3.

The parity contact dielectric layer PI of the second parity contact structure PS2 may include first and second sidewall parts SW1 and SW2 and a first connection part CO1. The parity contact PC of the second parity contact structure PS2 may include first and second parts P1 and P2. A minimum width in the first direction D1 of the second part P2 of the parity contact PC included in the second parity contact structure PS2 may be greater than a maximum width in the first direction D1 of the first part P1 of the parity contact PC included in the second parity contact structure PS2. A minimum width in the first direction D1 of the first part P1 of the parity contact PC included in the third parity contact structure PS3 may be less than a minimum width in the first direction D1 of the first part P1 of the parity contact PC included in the second parity contact structure PS2.

The connection contact dielectric layer CI of the seventh connection contact structure CS7 may include first, second, and third sidewall parts SW1, SW2, and SW3 and first and second connection parts CO1 and CO2.

The connection contact dielectric layer CI of each of the fifth and sixth connection contact structures CS5 and CS6 may include first and second sidewall parts SW1 and SW2 and a first connection part CO1.

A length in the third direction D3 of a parity contact dielectric layer PI of the third parity contact structure PS3 may be the same as a length in the third direction D3 of a connection contact dielectric layer CI of the fourth connection contact structure CS4. For example, the sum of the lengths in the third direction D3 of outer sidewalls of the parity contact dielectric layer PI of a parity contact structure PS (e.g., the third parity contact structure PS3) may be the same as the length in the third direction D3 of an outer sidewall of the connection contact dielectric layer CI of a connection contact structure CS (e.g., the fourth connection contact structure CS4). Herein, when a connection contact structure CS and a parity contact structure PS are in contact with an upper surface of the same conductive pattern CP, the connection contact dielectric layer CI of the connection contact structure CS and the parity contact dielectric layer PI of the parity contact structure PS may be referred to as having the same length in the third direction D3.

In some embodiments, a minimum width of the connection contact CC of the fourth connection contact structure CS4 (in the first direction D1) may be greater than a minimum width of the parity contact PC of the third parity contact structure PS3 (in the first direction D1). For example, a minimum width W1 in the first direction D1 of the connection contact CC of the fourth connection contact structure CS4 may be greater than a minimum width W2 in the first direction D1 of the parity contact PC of the third parity contact structure PS3.

In some embodiments, a conductive line may be provided on the parity contact PC of the third parity contact structure PS3, and the parity contact PC of the third parity contact structure PS3 may be electrically connected through the conductive line to the connection contact CC of the fourth connection contact structure CS4.

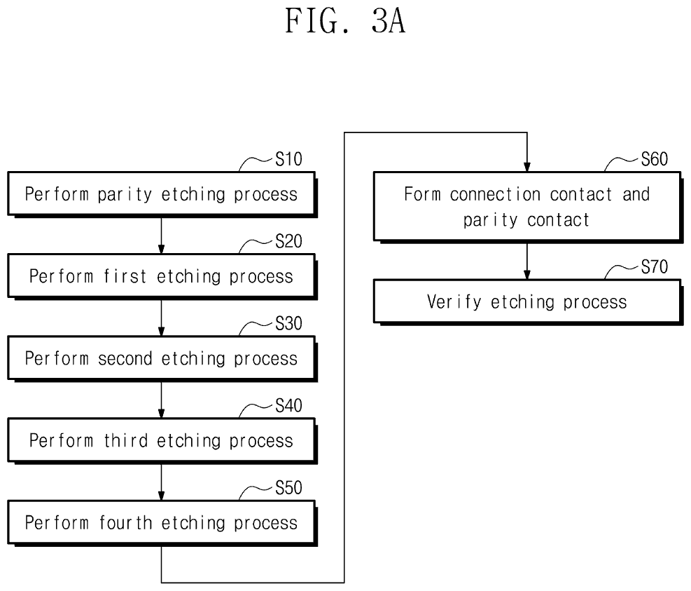

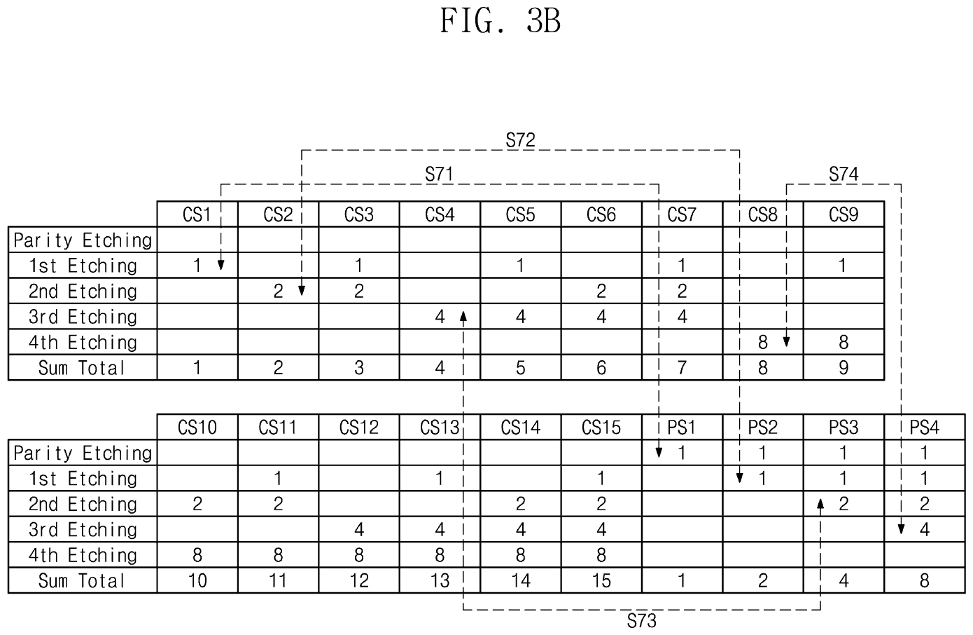

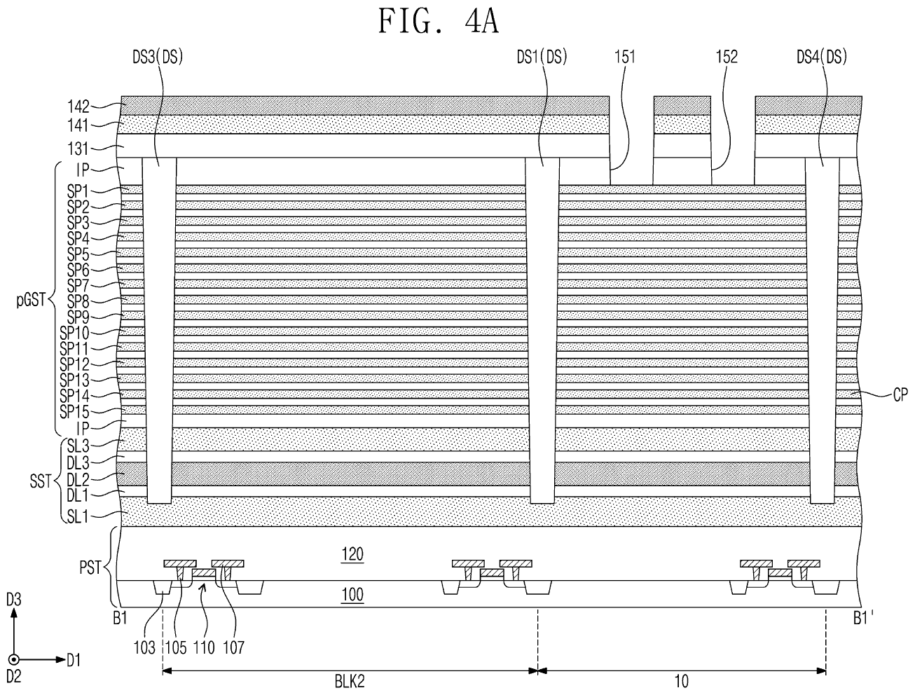

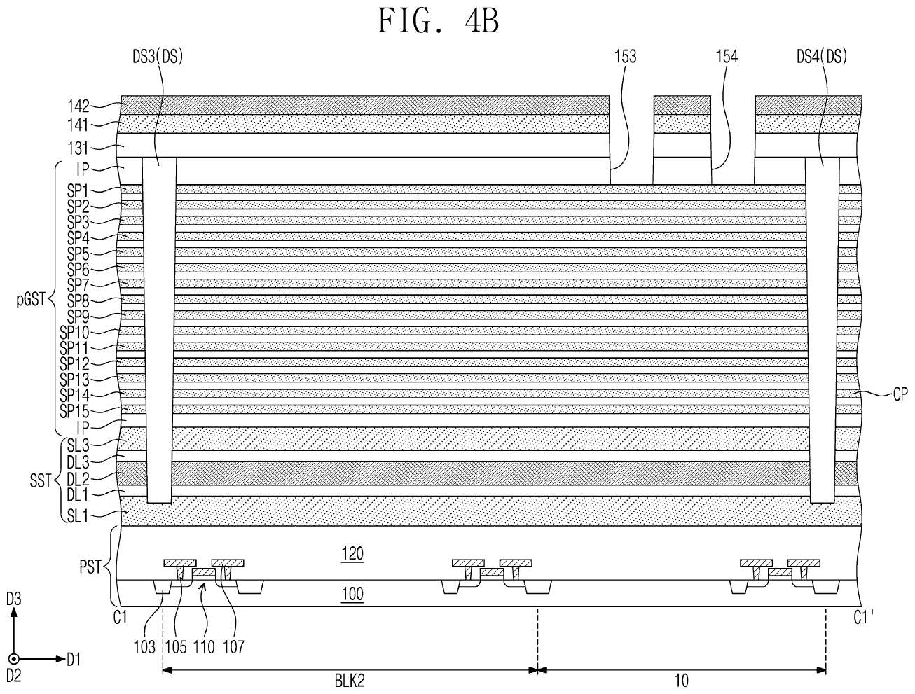

FIGS. 3A and 3B illustrate diagrams showing a method of manufacturing connection contact structures and parity contact structures according to FIGS. 2A to 2K. FIGS. 4A, 4B, 5A, 5B, 5C, 5D, 6A, 6B, 6C, 6D, 7A, 7B, 7C, 7D, 8A, 8B, 8C, 8D, 9A, 9B, 9C, and 9D illustrate cross-sectional views showing a method of fabricating a semiconductor device according to FIGS. 2A to 2K. In FIG. 3B, numerals may represent the number of sacrificial patterns newly exposed according to an etching process.

Referring to FIGS. 4A and 4B, a peripheral circuit structure PST may be formed. A source structure SST may be formed on the peripheral circuit structure PST. A preliminary gate stack structure pGST may be formed on the source structure SST. The preliminary gate stack structure pGST may include first to fifteenth sacrificial patterns SP1 to SP15 and dielectric patterns IP that are alternately stacked along the third direction D3. Each of the first to fifteenth sacrificial patterns SP1 to SP15 may include a dielectric material different from that of the dielectric pattern IP. For example, each of the first to fifteenth sacrificial patterns SP1 to SP15 may include nitride. The first to fifteenth sacrificial patterns SP1 to SP15 may be sequentially arranged along a direction opposite to the third direction D3. For example, the first sacrificial pattern SP1 may be the highest one of the sacrificial patterns SP, and the fifteenth sacrificial pattern SP15 may be the lowest one of the sacrificial patterns SP.

Separation structures DS, memory channel structures (see CH of FIG. 2B), and dummy structures (see DH of FIG. 2B) may be formed to penetrate the preliminary gate stack structure pGST. A first cover dielectric layer 131 may be formed on the preliminary gate stack structure pGST.

Referring to FIGS. 3A, 3B, 4A, and 4B, first to fifteenth connection contact structures CS1 to CS15 may be formed, and first to fourth parity contact structures PS1 to PS4 may be formed. Connection contact structures CS of first blocks (see BLK1 of FIG. 2A) may be formed simultaneously with the first to fifteenth connection contact structures CS1 to CS15 (in the second block BLK2).

The formation of the first to fifteenth connection contact structures CS1 to CS15 and the first to fourth parity contact structures PS1 to PS4 may include performing a parity etching process (S10), performing a first etching process (S20), performing a second etching process (S30), performing a third etching process (S40), performing a fourth etching process (S50), forming a connection contact and a parity contact (S60), and verifying an etching process (S70).

In the parity etching process S10, a hole may be formed to newly expose one sacrificial pattern on each of positions where the first to fourth parity contact structures PS1 to PS4 are formed (see FIG. 3B). In the parity etching process S10, a first hole 151 may be formed on a position where the first parity contact structure PS1 is formed, a second hole 152 may be formed on a position where the second parity contact structure PS2 is formed, a third hole 153 may be formed on a position where the third parity contact structure PS3 is formed, and a fourth hole 154 may be formed on a position where the fourth parity contact structure PS4 is formed. For example, on the position where the first parity contact structure PS1 is formed, the first hole 151 may newly expose the first sacrificial pattern SP1 covered with the dielectric pattern IP. In this description, the phrase “newly expose(s)” may denote that something not revealed in the previous process is exposed. The first, second, third, and fourth holes 151, 152, 153, and 154 may have their sidewalls defined by that of the first cover dielectric layer 131 and that of the dielectric pattern IP.

The formation of the first, second, third, and fourth holes 151, 152, 153, and 154 may include forming a first mask layer 141 on the first cover dielectric layer 131, forming a first photoresist pattern 142 on the first mask layer 141, and using the first photoresist pattern 142 to pattern the first mask layer 141, the first cover dielectric layer 131, and the dielectric pattern IP. The first photoresist pattern 142 and the first mask layer 141 may be removed after the formation of the first, second, third, and fourth holes 151, 152, 153, and 154. The first mask layer 141 may include a dielectric material. For example, the first mask layer 141 may include an amorphous carbon layer (ACL). The first photoresist pattern 142 may include a photoresist material.

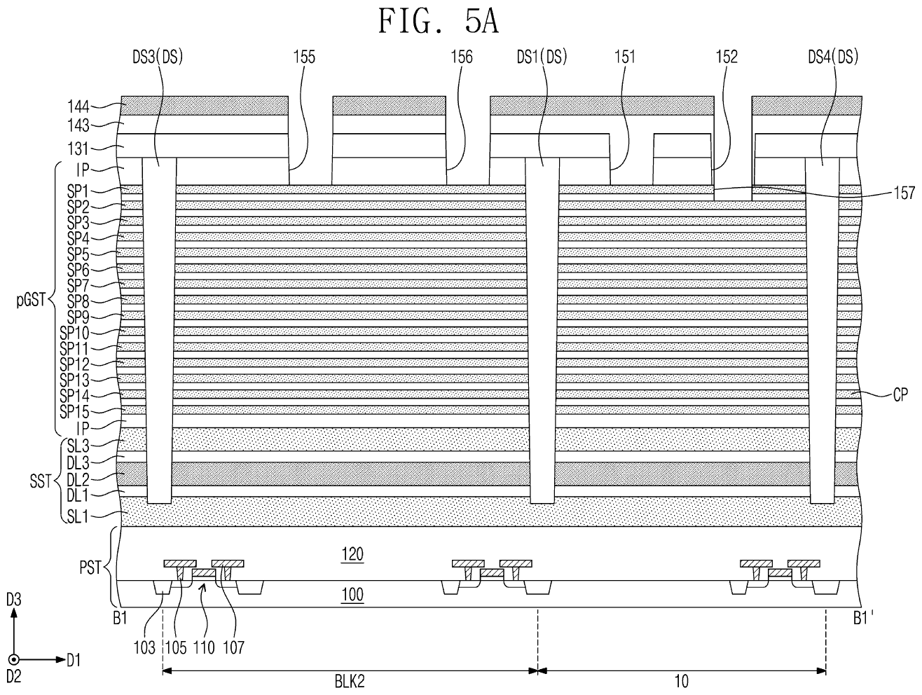

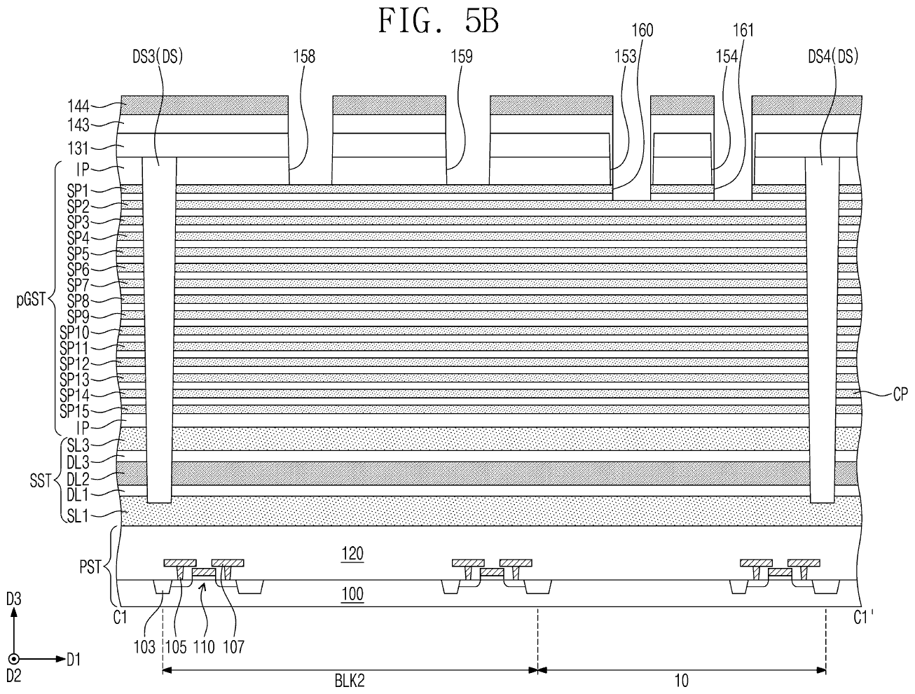

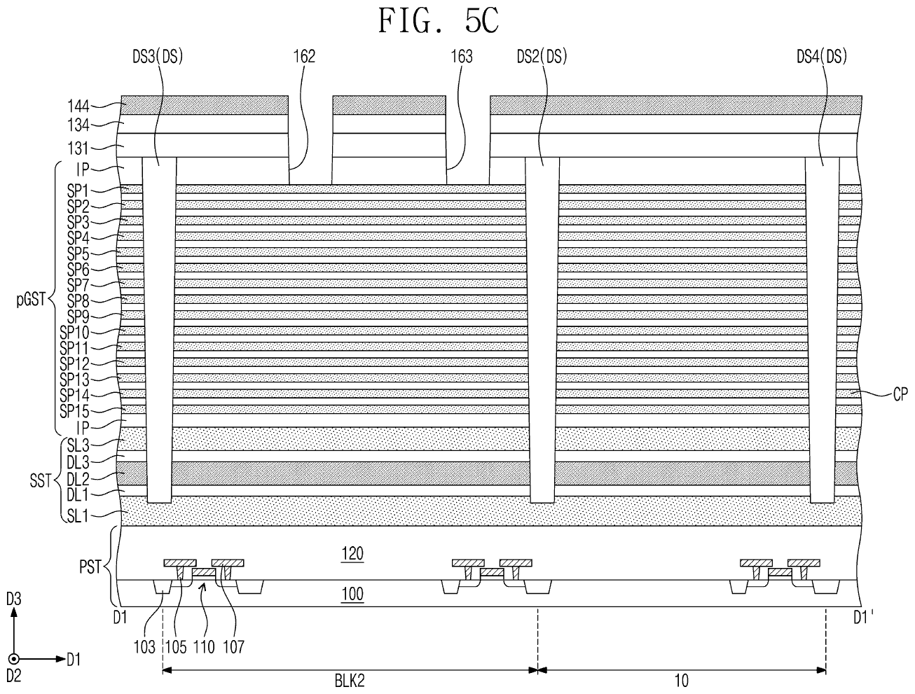

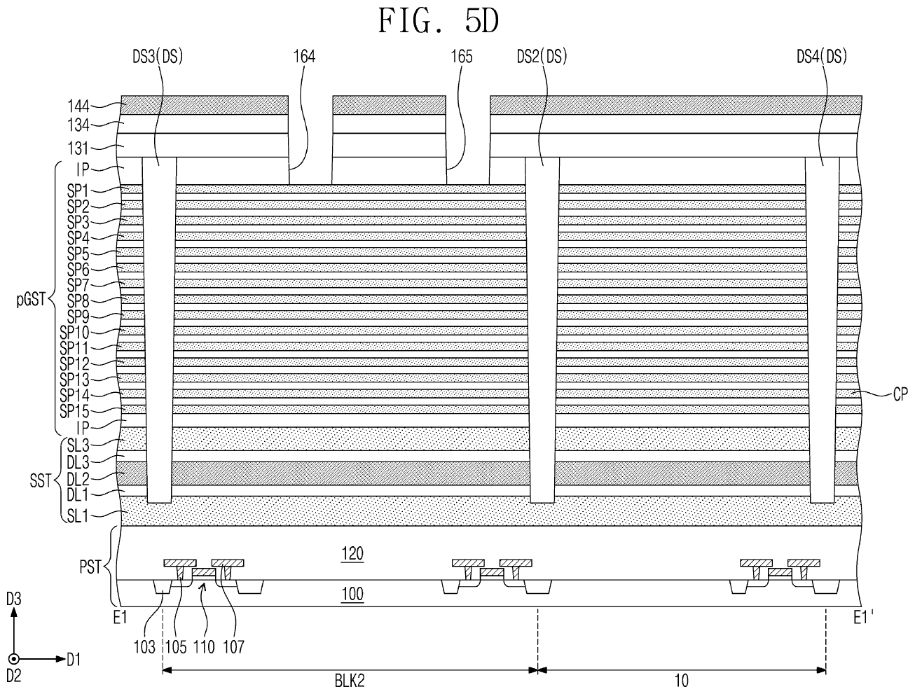

Referring to FIGS. 3A, 3B, 5A, 5B, 5C, and 5D, in the first etching process S20, a hole may be formed to newly expose one sacrificial pattern on each of positions for the formation of the first, third, fifth, seventh, ninth, eleventh, thirteenth, and fifteenth connection contact structures CS1, CS3, CS5, CS7, CS9, CS11, CS13, and CS15 and the second, third, and fourth parity contact structures PS2, PS3, and PS4 (see FIG. 3B).

In the first etching process S20, fifth to fifteenth holes 155 to 165 may be formed. The fifth hole 155 may be formed on the position where the first connection contact structure CS1 is formed, the sixth hole 156 may be formed on the position where the third connection contact structure CS3 is formed, the eighth hole 158 may be formed on the position where the fifth connection contact structure CS5 is formed, the ninth hole 159 may be formed on the position where the seventh connection contact structure CS7 is formed, the twelfth hole 162 may be formed on the position where the ninth connection contact structure CS9 is formed, the thirteenth hole 163 may be formed on the position where the eleventh connection contact structure CS11 is formed, the fourteenth hole 164 may be formed on the position where the thirteenth connection contact structure CS13 is formed, the fifteenth hole 165 may be formed on the position where the fifteenth connection contact structure CS15 is formed, the seventh hole 157 may be formed on the position where the second parity contact structure PS2 is formed, the tenth hole 160 may be formed on the position where the third parity contact structure PS3 is formed, and the eleventh hole 161 may be formed on the position where the fourth parity contact structure PS4 is formed. For example, on the position where the first connection contact structure CS1 is formed, the fifth hole 155 may newly expose the first sacrificial pattern SP1 covered with the dielectric pattern IP, and on the position where the second parity contact structure PS2 is formed, the seventh hole 157 may newly expose the second sacrificial pattern SP2 covered with the dielectric pattern IP.

The fifth, sixth, eighth, ninth, twelfth, thirteenth, fourteenth, and fifteenth holes 155, 156, 158, 159, 162, 163, 164, and 165 may have their sidewalls defined by that of the first cover dielectric layer 131 and that of the dielectric pattern IP. The seventh, tenth, and eleventh holes 157, 160, and 161 may have their sidewalls defined by that of the first sacrificial pattern SP1 and that of the dielectric pattern IP.

The formation of the fifth to fifteenth holes 155 to 165 may include forming a second mask layer 143, forming a second photoresist pattern 144 on the second mask layer 143, and using the second photoresist pattern 144 to perform a patterning process. The second photoresist pattern 144 and the second mask layer 143 may be removed after the formation of the fifth to fifteenth holes 155 to 165. The second mask layer 143 may include a dielectric material. The second photoresist pattern 144 may include a photoresist material.

The formation of the second mask layer 143 may include (at least partially) filling the first to fourth holes 151 to 154 with the second mask layer 143. Based on the patterning process using the second photoresist pattern 144, portions of the second, third, and fourth holes 152, 153, and 154 may be opened again, and the seventh, tenth, and eleventh holes 157, 160, and 161 may be formed. The seventh hole 157 may overlap in the third direction D3 with the second hole 152. The tenth hole 160 may overlap in the third direction D3 with the third hole 153. The eleventh hole 161 may overlap in the third direction D3 with the fourth hole 154. A maximum width in a first direction D1 of the seventh hole 157 may be less than a minimum width in the first direction D1 of the second hole 152. The seventh hole 157 may be located at a lower level than that of the second hole 152.

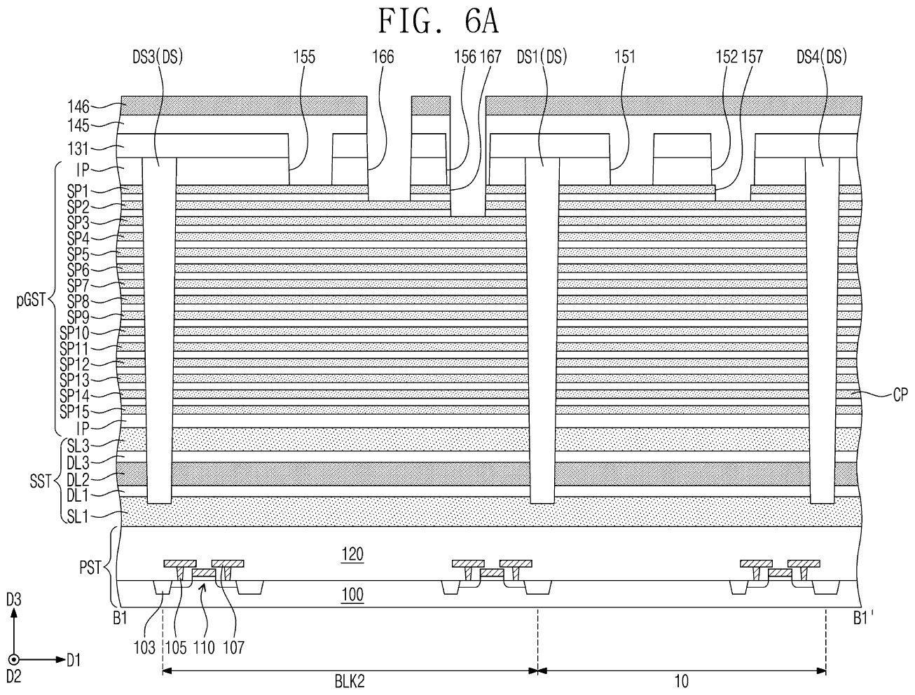

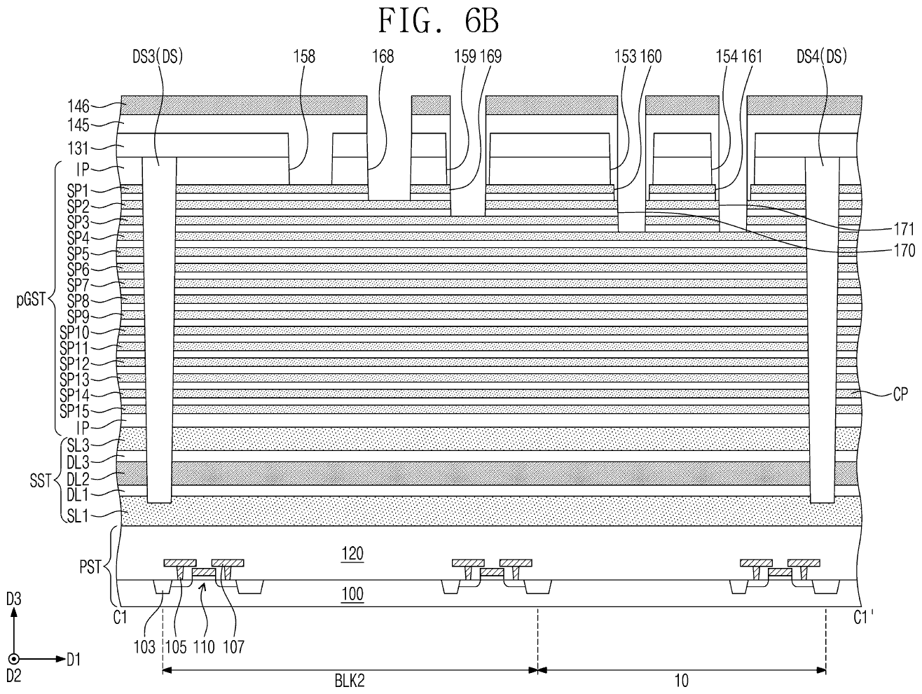

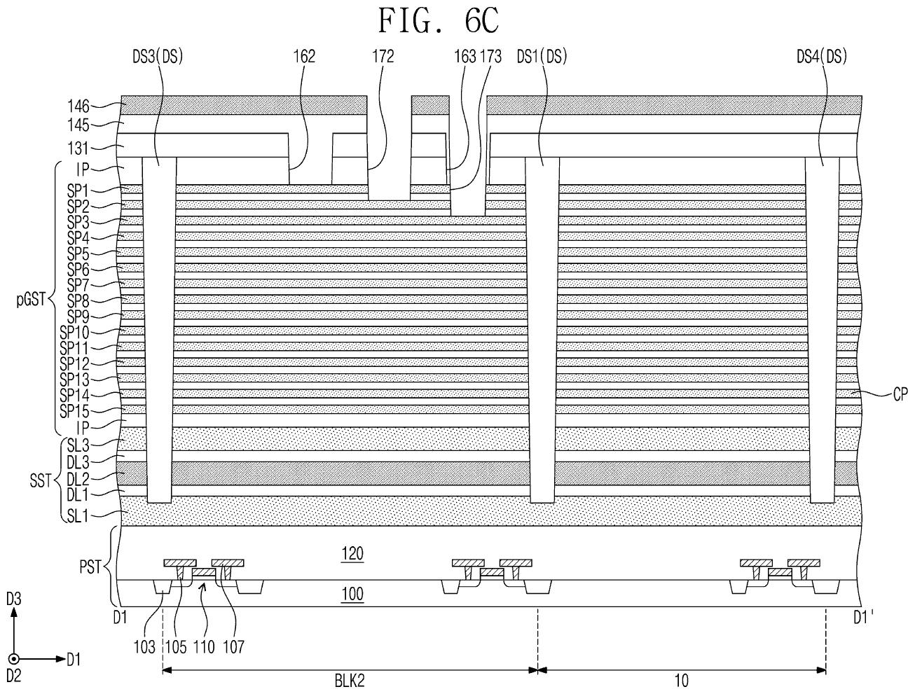

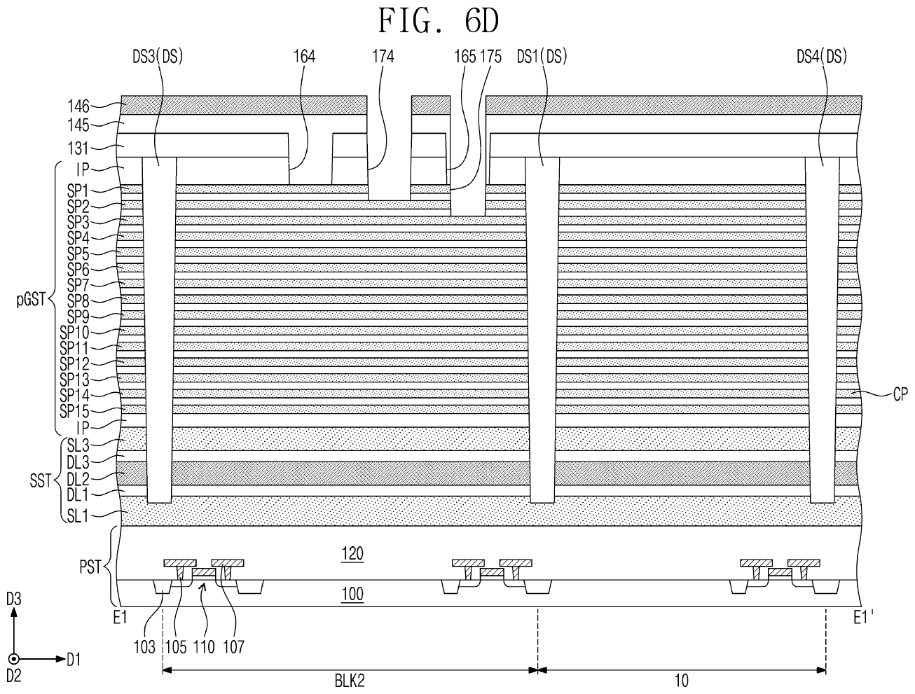

Referring to FIGS. 3A, 3B, 6A, 6B, 6C, and 6D, in the second etching process S30, a hole may be formed to newly expose two sacrificial patterns on each of positions for the formation of the second, third, sixth, seventh, tenth, eleventh, fourteenth, and fifteenth connection contact structures CS2, CS3, CS6, CS7, CS10, CS11, CS14, and CS15 and the third and fourth parity contact structures PS3 and PS4 (see FIG. 3B).

In the second etching process S30, sixteenth to twenty-fifth holes 166 to 175 may be formed. The sixteenth hole 166 may be formed on the position where the second connection contact structure CS2 is formed, the seventeenth hole 167 may be formed on the position where the third connection contact structure CS3 is formed, the eighteenth hole 168 may be formed on the position where the sixth connection contact structure CS6 is formed, the nineteenth hole 169 may be formed on the position where the seventh connection contact structure CS7 is formed, the twenty-second hole 172 may be formed on the position where the tenth connection contact structure CS10 is formed, the twenty-third hole 173 may be formed on the position where the eleventh connection contact structure CS11 is formed, the twenty-fourth hole 174 may be formed on the position where the fourteenth connection contact structure CS14 is formed, the twenty-fifth hole 175 may be formed on the position where the fifteenth connection contact structure CS15 is formed, the twentieth hole 170 may be formed on the position where the third parity contact structure PS3 is formed, and the twenty-first hole 171 may be formed on the position where the fourth parity contact structure PS4 is formed.

For example, on the position where the third connection contact structure CS3 is formed, the seventeenth hole 167 may newly expose the second and third sacrificial patterns SP2 and SP3 that are covered with the dielectric patterns IP, and on the position where the third parity contact structure PS3 is formed, the twentieth hole 170 may newly expose the third and fourth sacrificial patterns SP3 and SP4 that are covered with the dielectric patterns IP.

The formation of the sixteenth to twenty-fifth holes 166 to 175 may include forming a third mask layer 145, forming a third photoresist pattern 146 on the third mask layer 145, and using the third photoresist pattern 146 to perform a patterning process. The third photoresist pattern 146 and the third mask layer 145 may be removed after the formation of the sixteenth to twenty-fifth holes 166 to 175. The third mask layer 145 may include a dielectric material. The third photoresist pattern 146 may include a photoresist material. The formation of the third mask layer 145 may include (at least partially) filling the first to fifteenth holes 151 to 165 with the third mask layer 145.

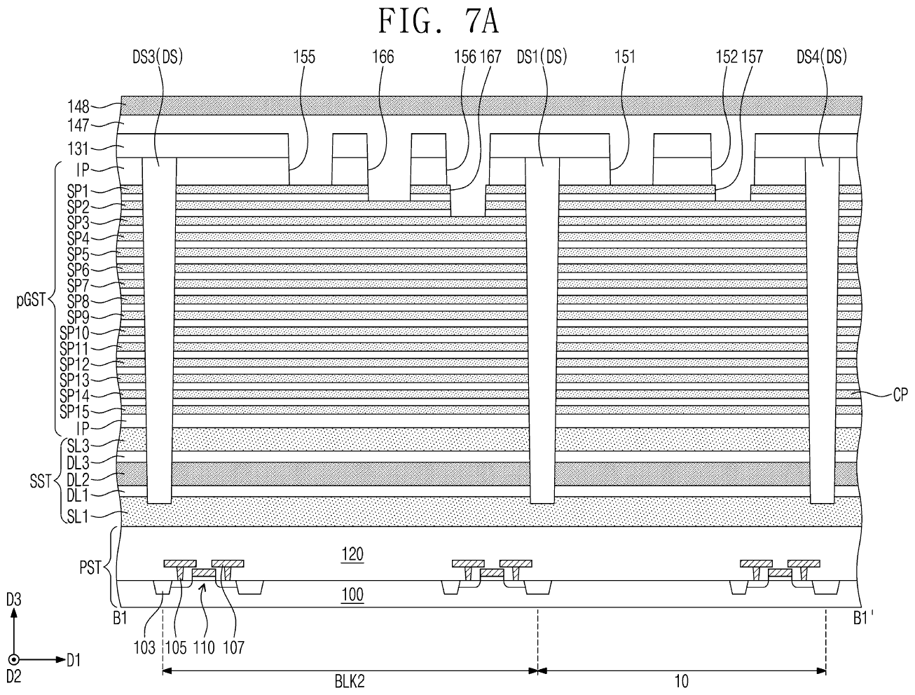

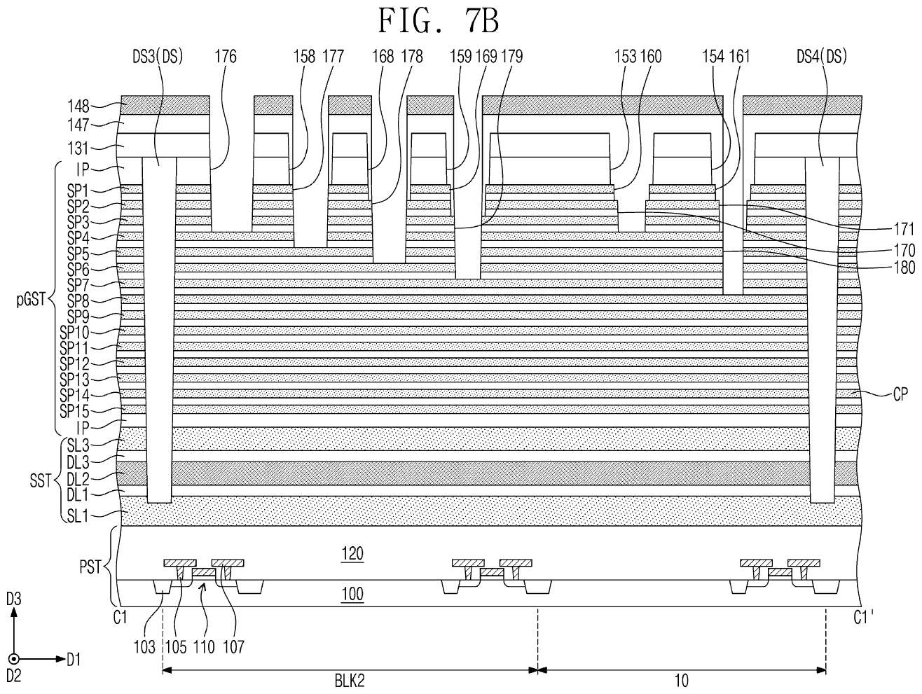

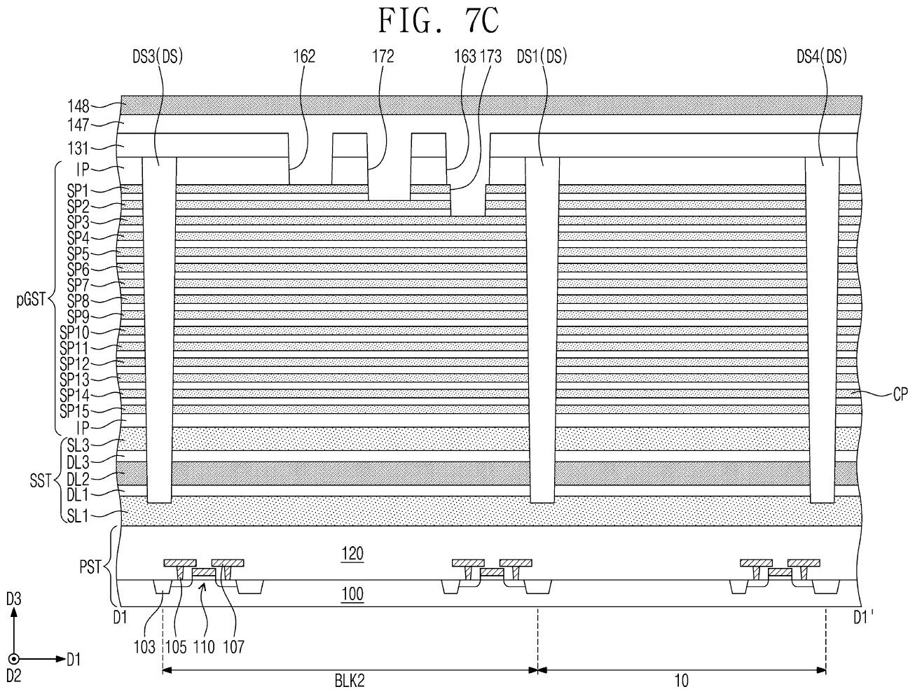

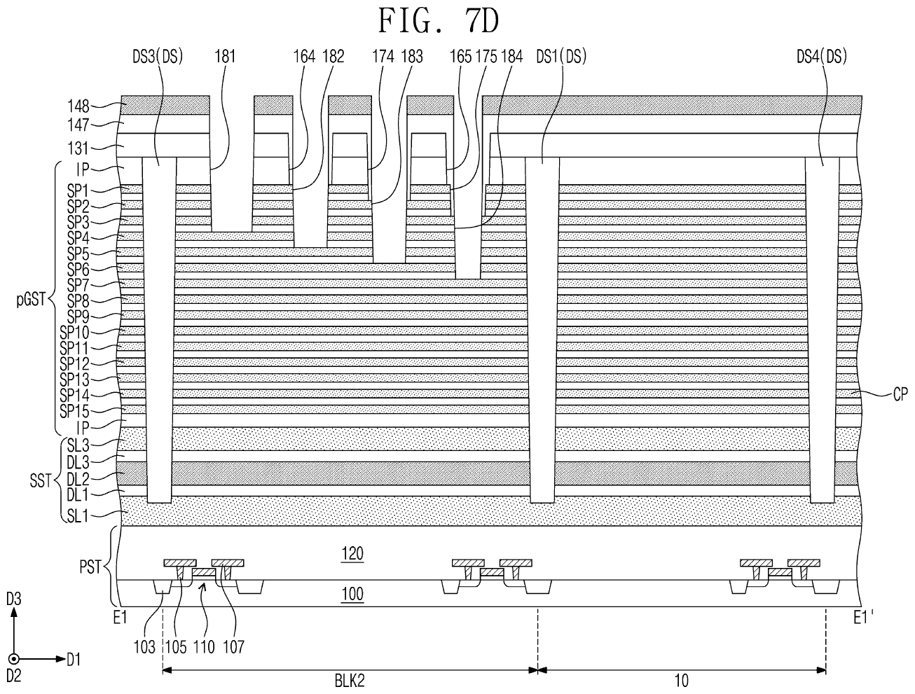

Referring to FIGS. 3A, 3B, 7A, 7B, 7C, and 7D, in the third etching process S40, a hole may be formed to newly expose four sacrificial patterns on each of positions for the formation of the fourth, fifth, sixth, seventh, twelfth, thirteenth, fourteenth, and fifteenth connection contact structures CS4, CS5, CS6, CS7, CS12, CS13, CS14, and CS15 and the fourth parity contact structure PS4 (see FIG. 3B).

In the third etching process S40, twenty-sixth to thirty-fourth holes 176 to 184 may be formed. The twenty-sixth hole 176 may be formed on the position where the fourth connection contact structure CS4 is formed, the twenty-seventh hole 177 may be formed on the position where the fifth connection contact structure CS5 is formed, the twenty-eighth hole 178 may be formed on the position where the sixth connection contact structure CS6 is formed, the twenty-ninth hole 179 may be formed on the position where the seventh connection contact structure CS7 is formed, the thirty-first hole 181 may be formed on the position where the twelfth connection contact structure CS12 is formed, the thirty-second hole 182 may be formed on the position where the thirteenth connection contact structure CS13 is formed, the thirty-third hole 183 may be formed on the position where the fourteenth connection contact structure CS14 is formed, the thirty-fourth hole 184 may be formed on the position where the fifteenth connection contact structure CS15 is formed, and the thirtieth hole 180 may be formed on the position where the fourth parity contact structure PS4 is formed.

For example, on the position where the seventh connection contact structure CS7 is formed, the twenty-ninth hole 179 may newly expose the fourth, fifth, sixth, and seventh sacrificial patterns SP4, SP5, SP6, and SP7 that are covered with the dielectric patterns IP, and on the position where the fourth parity contact structure PS4 is formed, the thirtieth hole 180 may newly expose the fifth, sixth, seventh, and eighth sacrificial patterns SP5, SP6, SP7, and SP8 that are covered with the dielectric patterns IP. The twenty-ninth hole 179 may overlap in the third direction D3 with the ninth and nineteenth holes 159 and 169, and the thirtieth hole 180 may overlap in the third direction D3 with the eleventh and twenty-first holes 161 and 171.

The formation of the twenty-sixth to thirty-fourth holes 176 to 184 may include forming a fourth mask layer 147, forming a fourth photoresist pattern 148 on the fourth mask layer 147, and using the fourth photoresist pattern 148 to perform a patterning process. The fourth photoresist pattern 148 and the fourth mask layer 147 may be removed after the formation of the twenty-sixth to thirty-fourth holes 176 to 184. The fourth mask layer 147 may include a dielectric material. The fourth photoresist pattern 148 may include a photoresist material. The formation of the fourth mask layer 147 may include (at least partially) filling the first to twenty-fifth holes 151 to 175 with the fourth mask layer 147.

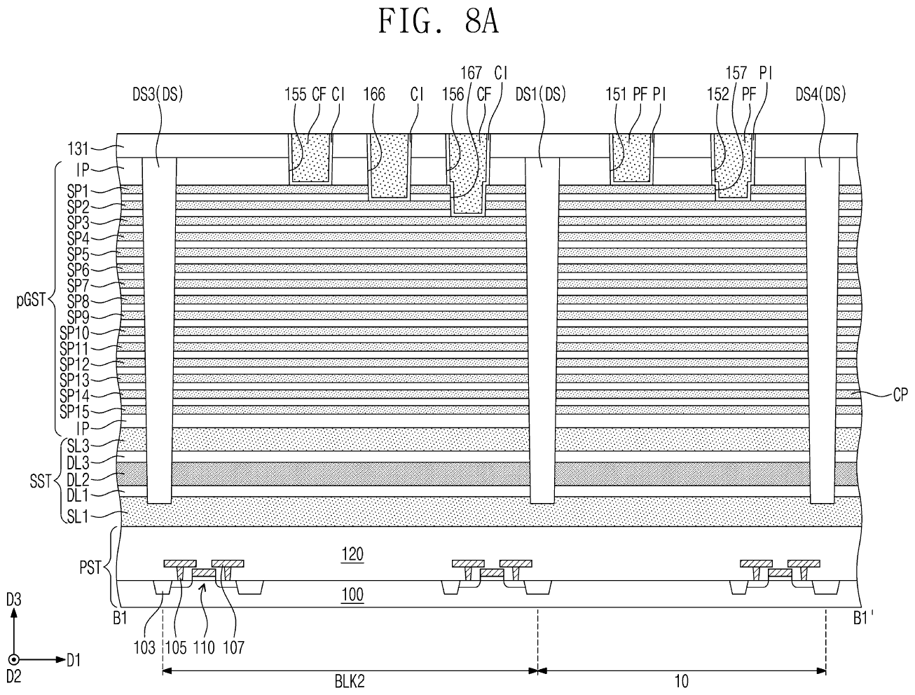

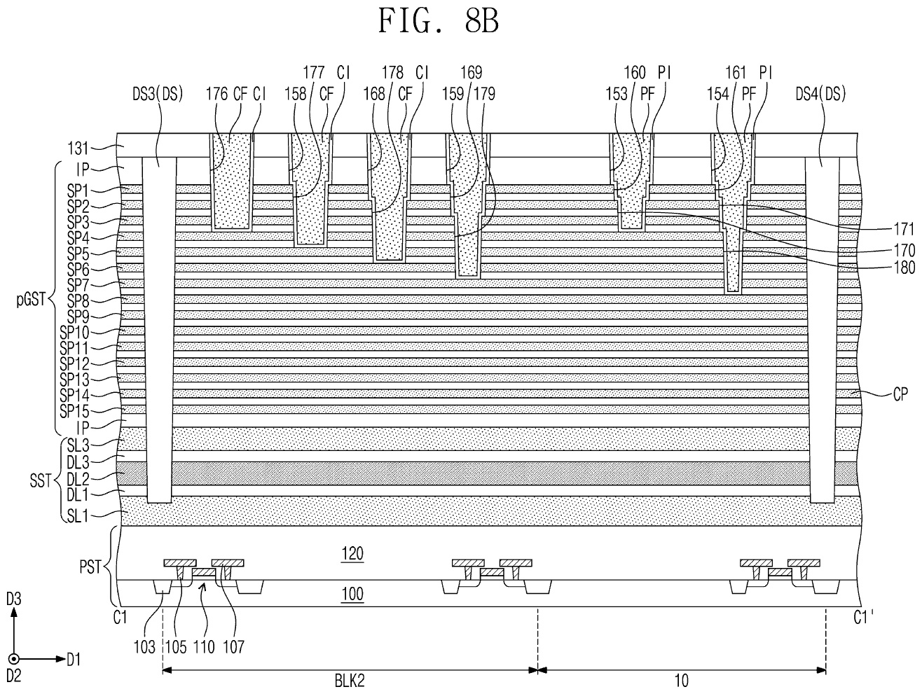

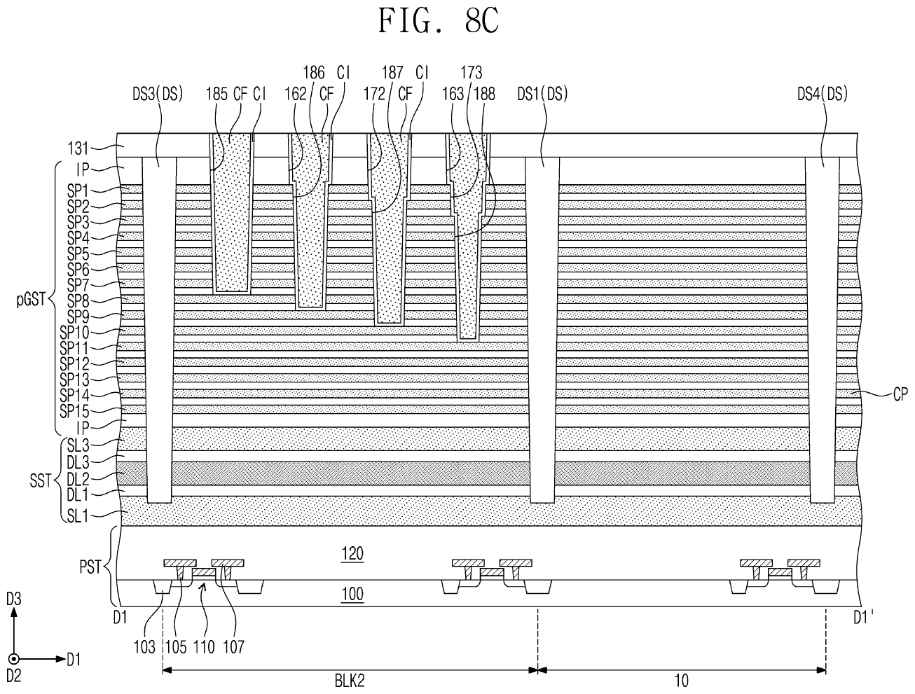

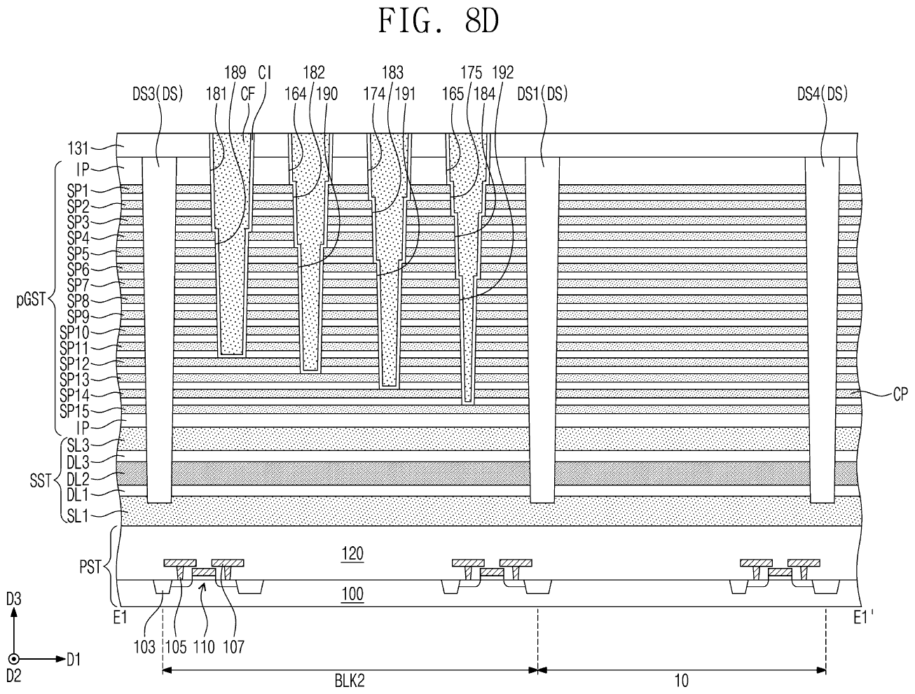

Referring to FIGS. 3A, 3B, 8A, 8B, 8C, and 8D, in the fourth etching process S50, a hole may be formed to newly expose eight sacrificial patterns on each of positions for the formation of the eighth, ninth, tenth, eleventh, twelfth, thirteenth, fourteenth, and fifteenth connection contacts structures CS8, CS9, CS10, CS11, CS12, CS13, CS14, and CS15 (see FIG. 3B).

In the fourth etching process S50, thirty-fifth to forty-second holes 185 to 192. The thirty-fifth hole 185 may be formed on the position where the eighth connection contact structure CS8 is formed, the thirty-sixth hole 186 may be formed on the position where the ninth connection contact structure CS9 is formed, the thirty-seventh hole 187 may be formed on the position where the tenth connection contact structure CS10 is formed, the thirty-eighth hole 188 may be formed on the position where the eleventh connection contact structure CS11 is formed, the thirty-ninth hole 189 may be formed on the position where the twelfth connection contact structure CS12 is formed, the fortieth hole 190 may be formed on the position where the thirteenth connection contact structure CS13 is formed, the forty-first hole 191 may be formed on the position where the fourteenth connection contact structure CS14 is formed, and the forty-second hole 192 may be formed on the position where the fifteenth connection contact structure CS15 is formed.

For example, on the position where the eleventh connection contact structure CS11 is formed, the thirty-eighth hole 188 may newly expose the fourth to eleventh sacrificial patterns SP4 to SP11 that are covered with the dielectric patterns IP. The thirty-eighth hole 188 may overlap in the third direction D3 with the thirteenth and twenty-third holes 163 and 173.

The formation of the thirty-fifth to forty-second holes 185 to 192 may include forming a fifth mask layer and a fifth photoresist pattern, and using the fifth photoresist pattern to perform a patterning process.

Connection contact dielectric layers CI, parity contact dielectric layers PI, connection sacrificial layers CF, and parity sacrificial layers PF may be formed in the first to forty-second holes 151 to 192. The connection sacrificial layer CF may be formed on the connection contact dielectric layer CI. For example, the connection contact dielectric layer CI may extend around the connection sacrificial layer CF. The connection sacrificial layer CF may include, for example, polysilicon. The parity sacrificial layer PF may be formed on the parity contact dielectric layer PI. For example, the parity contact dielectric layer PI may extend around the parity sacrificial layer PF. The parity sacrificial layer PF may include, for example, polysilicon.

For example, on the position where the eleventh connection contact structure CS11 is formed, the connection contact dielectric layer CI and the connection sacrificial layer CF may be formed in the thirteenth, twenty-third, and thirty-eighth holes 163, 173, and 188, and on the position where the fourth parity contact structure PS4 is formed, the parity contact dielectric layer PI and the parity sacrificial layer PF may be formed in the fourth, eleventh, twenty-first, and thirtieth holes 154, 161, 171, and 180.

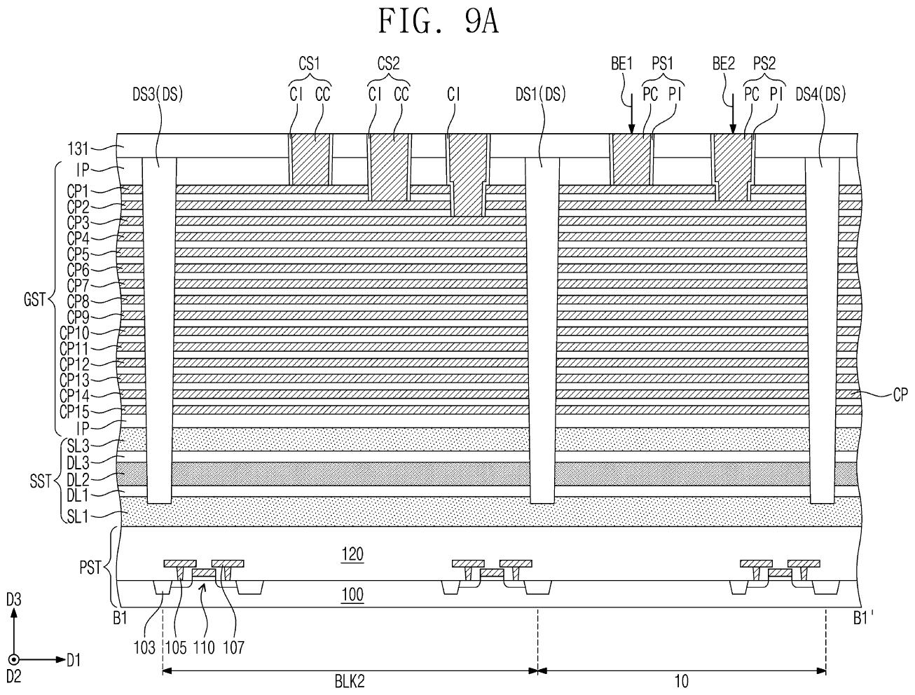

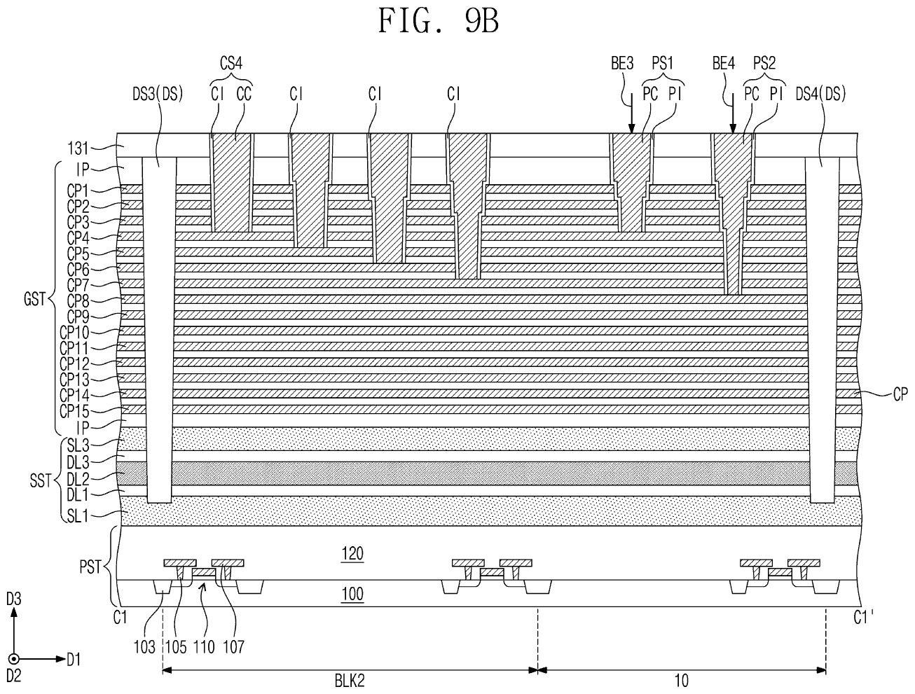

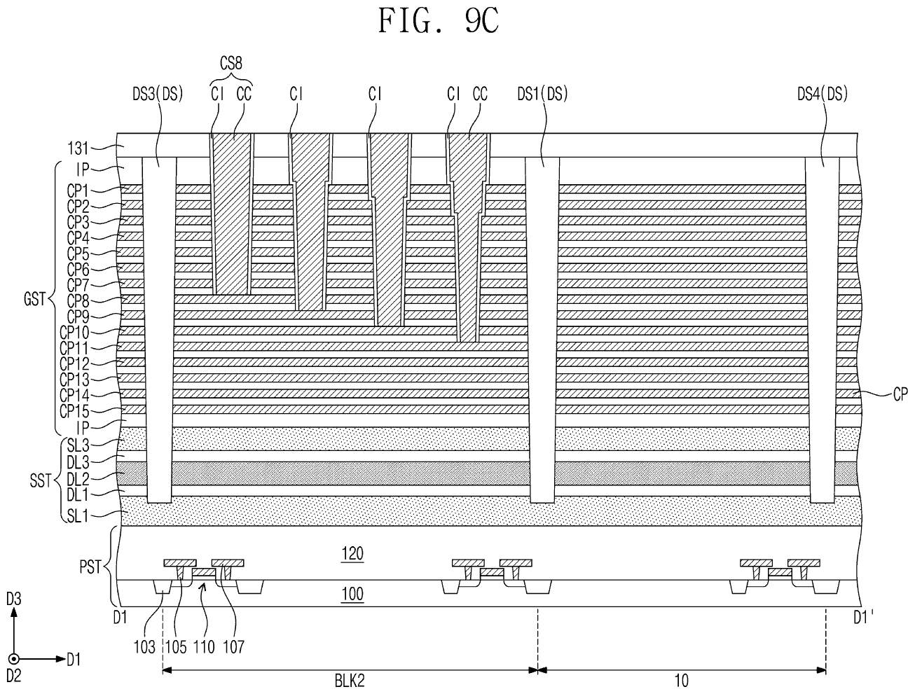

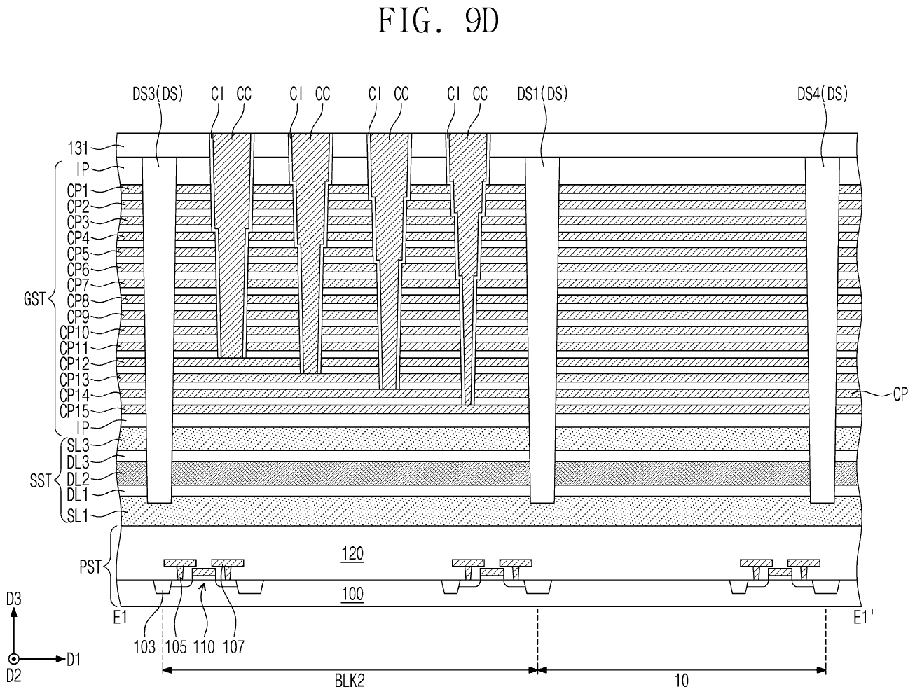

Referring to FIGS. 3A, 3B, 9A, 9B, 9C, and 9D, the first to fifteenth sacrificial patterns SP1 to SP15 may be replaced with first to fifteenth conductive patterns CP1 to CP15. The replacement of the first to fifteenth sacrificial patterns SP1 to SP15 with the first to fifteenth conductive patterns CP1 to CP15 may include removing the first to fifteenth sacrificial patterns SP1 to SP15, and forming the first to fifteenth conductive patterns CP1 to CP15 in empty spaces formed by the removal of the first to fifteenth sacrificial patterns SP1 to SP15.

The connection sacrificial layers CF and the parity sacrificial layers PF may be removed. The removal of the connection sacrificial layers CF and the parity sacrificial layers PF may expose the connection contact dielectric layers CI and the parity contact dielectric layers PI.

There may be removed lower portions of the connection contact dielectric layers CI and the parity contact dielectric layers PI. For example, an etch-back process may be employed to remove the lower portions of the connection contact dielectric layers CI and the parity contact dielectric layers PI. In some embodiments, the lower portions of the connection contact dielectric layers CI and the parity contact dielectric layers PI may refer to portions between sidewall portions of the connection contact dielectric layers CI and the parity contact dielectric layers PI in the first direction D1, respectively. The removal of the lower portions of the connection contact dielectric layers CI and the parity contact dielectric layers PI may expose the first to fifteenth conductive patterns CP1 to CP15.

Connection contacts CC and parity contacts PC may be formed (S60). An etching process may be verified (S70). The etching process verification S70 may include irradiating an electron beam, and comparing color or brightness of light from the irradiation of the electron beam. A first electron beam BE1 may be irradiated to the parity contact PC of the first parity contact structure PS1 and the connection contact CC of the first connection contact structure CS1, and comparing colors and/or brightness of light emitted from the parity contact PC of the first parity contact structure PS1 by the first electron beam BE1 and from the connection contact CC of the first connection contact structure CS1 by the first electron beam BE1 (S71). The comparison of the colors and/or brightness of light may determine whether the parity contact PC of the first parity contact structure PS1 and the connection contact CC of the first connection contact structure CS1 are electrically connected to the first conductive pattern CP1, and may also determine whether the first etching process S20 was performed to an appropriate depth.

A second electron beam BE2 may be irradiated to the parity contact PC of the second parity contact structure PS2 and the connection contact CC of the second connection contact structure CS2, and comparing colors and/or brightness of light emitted from the parity contact PC of the second parity contact structure PS2 by the second electron beam BE2 and from the connection contact CC of the second connection contact structure CS2 by the second electron beam BE2 (S72). The comparison of the colors and/or brightness of light may determine whether the parity contact PC of the second parity contact structure PS2 and the connection contact CC of the second connection contact structure CS2 are electrically connected to the second conductive pattern CP2, and may also determine whether the second etching process S30 was performed to an appropriate depth.

A third electron beam BE3 may be irradiated to the parity contact PC of the third parity contact structure PS3 and the connection contact CC of the fourth connection contact structure CS4, and comparing colors and/or brightness of light emitted from the parity contact PC of the third parity contact structure PS3 by the third electron beam BE3 and from the connection contact CC of the fourth connection contact structure CS4 by the third electron beam BE3 (S73). The comparison of the colors and/or brightness of light may determine whether the parity contact PC of the third parity contact structure PS3 and the connection contact CC of the fourth connection contact structure CS4 are electrically connected to the fourth conductive pattern CP4, and may also determine whether the third etching process S40 was performed to an appropriate depth.

A fourth electron beam BE4 may be irradiated to the parity contact PC of the fourth parity contact structure PS4 and the connection contact CC of the eighth connection contact structure CS8, and comparing colors and/or brightness of light emitted from the parity contact PC of the fourth parity contact structure PS4 by the fourth electron beam BE4 and from the connection contact CC of the eighth connection contact structure CS8 by the fourth electron beam BE4 (S74). The comparison of the colors and/or brightness of light may determine whether the parity contact PC of the fourth parity contact structure PS4 and the connection contact CC of the eighth connection contact structure CS8 are electrically connected to the eighth conductive pattern CP8, and may also determine whether the fourth etching process S50 was performed to an appropriate depth.

In some embodiments, in the etching process verification S70, before the formation of the connection contacts CC and the parity contacts PC, an electron beam may be irradiated to a conductive pattern, and color and/or brightness of light emitted from the conductive pattern may be compared.

In some embodiments, the second block BLK2 and the parity region 10 of the semiconductor device may include (16×N)−1 conductive patterns, and the semiconductor device may be fabricated through a parity etching process, an etching process, and an etching verification process that are performed N+3 times (where, Nis 1, 2, 4, 8, 16, . . . ).

Bit-line contacts BC may be formed. A second cover dielectric layer 132 may be formed on the first cover dielectric layer 131. Bit lines BL and conductive lines CL may be formed.

In a method of fabricating a semiconductor device according to some embodiments, the parity region 10 may be used to perform an etching process and a verification process, and thus the performed etching process may be verified before a subsequent etching process is performed. Therefore, the etching process may be verified in real time, and the semiconductor device may improve in reliability.

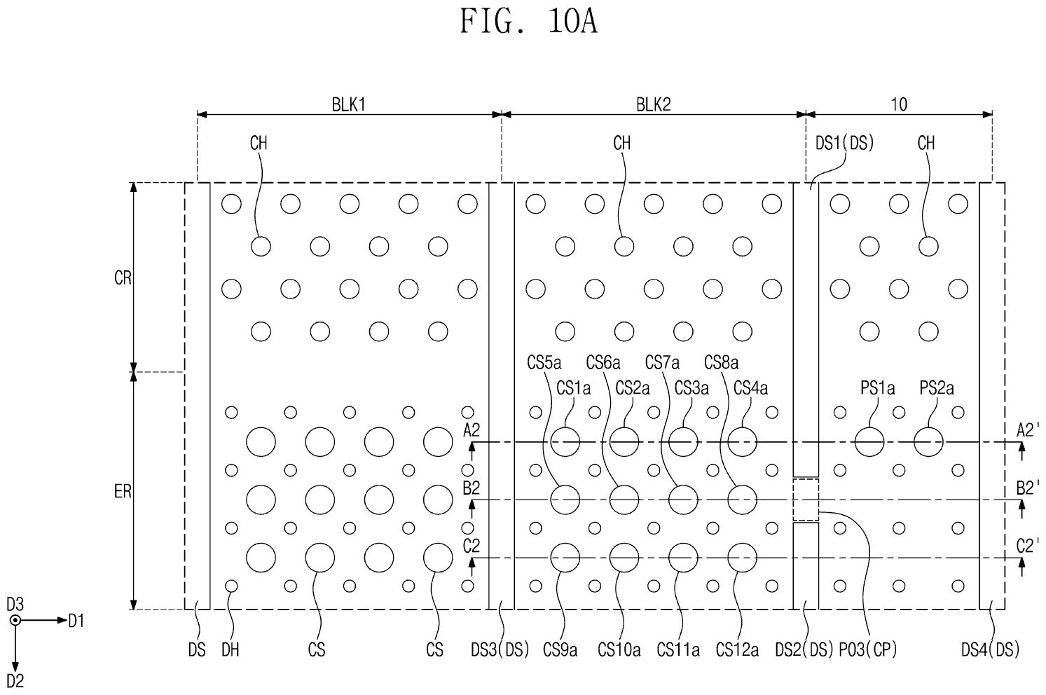

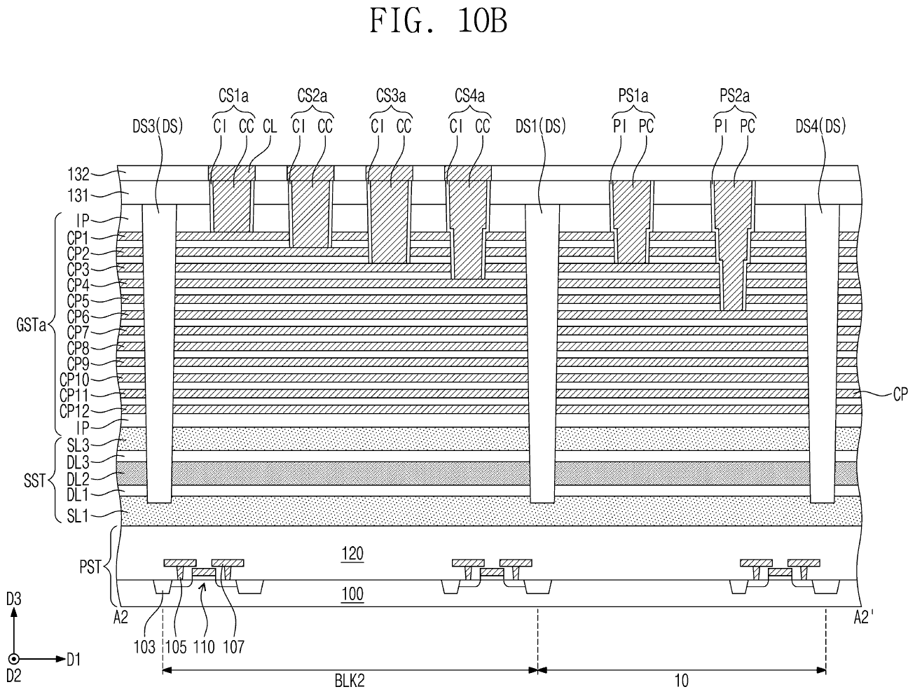

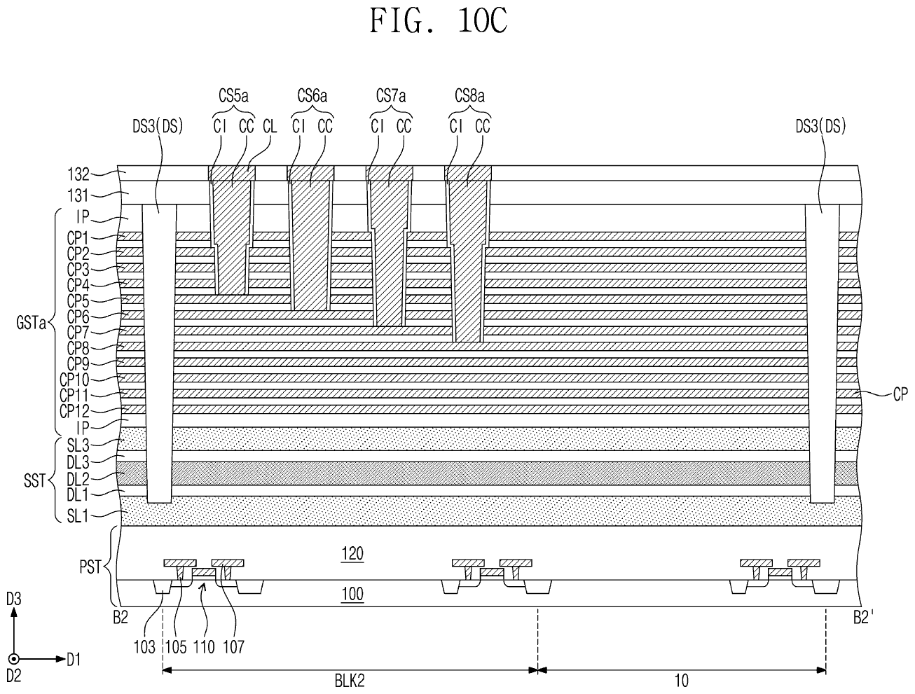

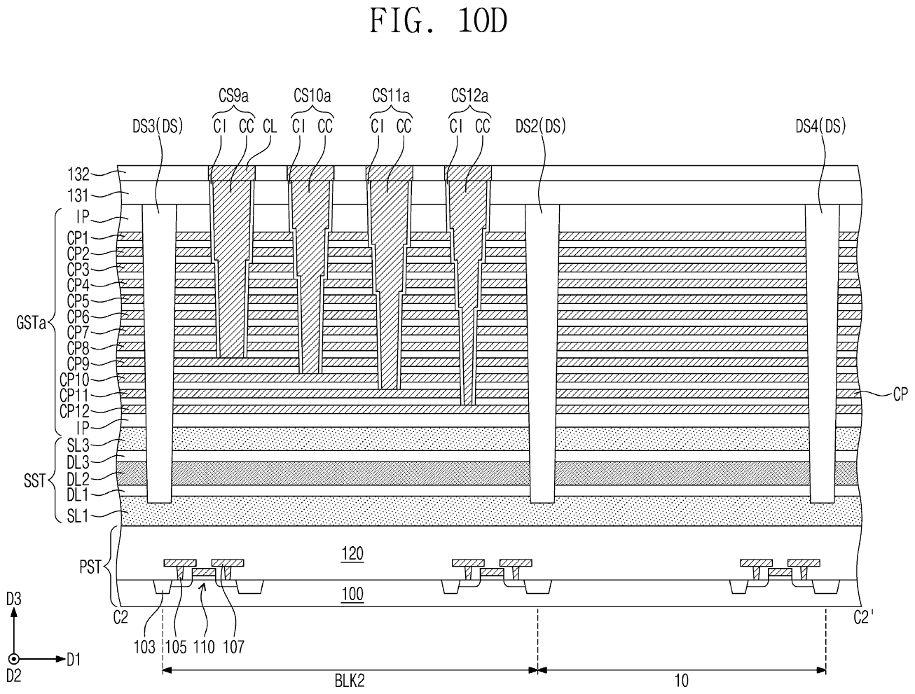

FIG. 10A illustrates a plan view showing a semiconductor device according to some embodiments. FIG. 10B illustrates a cross-sectional view taken along line A2-A2′ of FIG. 10A. FIG. 10C illustrates a cross-sectional view taken along line B2-B2′ of FIG. 10A. FIG. 10D illustrates a cross-sectional view taken along line C2-C2′ of FIG. 10A. Except that discussed below, a semiconductor device according to FIGS. 10A to 10D may be similar to the semiconductor device according to FIGS. 2A to 2K.

Referring to FIGS. 10A, 10B, 10C, and 10D, the second block BLK2 may include first to twelfth connection contact structures CS1a to CS12a. The parity region 10 may include first and second parity contact structures PS1a and PS2a. A gate stack structure GSTa may include first to twelfth conductive patterns CP1 to CP12.

The first to twelfth connection contact structures CS1a to CS12a may be correspondingly electrically connected to the first to twelfth conductive patterns CP1 to CP12. For example, the sixth connection contact structure CS6a may be electrically connected to the sixth conductive pattern CP6, and the third connection contact structure CS3a may be electrically connected to the third conductive pattern CP3.

The first parity contact structure PS1a may be electrically connected to the third conductive pattern CP3. The second parity contact structure PS2a may be electrically connected to the sixth conductive pattern CP6.

Each of the first to twelfth connection contact structures CS1a to CS12a may include a connection contact CC and a connection contact dielectric layer CI. Each of the first and second parity contact structures PS1a and PS2a may include a parity contact PC and a parity contact dielectric layer PI.

The connection contact dielectric layer CI of each of the first, second, third, and sixth connection contact structures CS1a, CS2a, CS3a, and CS6a may include one sidewall part. The connection contact dielectric layer CI of each of the fourth, fifth, seventh, eighth, and ninth connection contact structures CS4a, CS5a, CS7a, CS8a, and CS9a may include two sidewall parts and one connection part. The connection contact dielectric layer CI of each of the tenth and eleventh connection contact structures CS10a and CS11a may include three sidewall parts and two connection parts. The connection contact dielectric layer CI of the twelfth connection contact dielectric layer CS12a may include four sidewall parts and three connection parts. The parity contact dielectric layer PI of the first parity contact structure PS1a may include two sidewall parts and one connection part. The parity contact dielectric layer PI of the second parity contact structure PS2a may include three sidewall parts and two connection part.

The number of conductive patterns in contact with each of the first and second parity contact structures PS1a and PS2a may be a multiple of three. The first parity contact structure PS1a may be in contact with the first to third conductive patterns CP1 to CP3. The second parity contact structure PS2a may be in contact with the first to sixth conductive patterns CP1 to CP6.

In some embodiments, the second block BLK2 and the parity region 10 of the semiconductor device may include 12×N conductive patterns, 12×N connection contact structures, and N+1 parity contact structures (where, N is 1, 2, 4, 8, 16, . . . ).

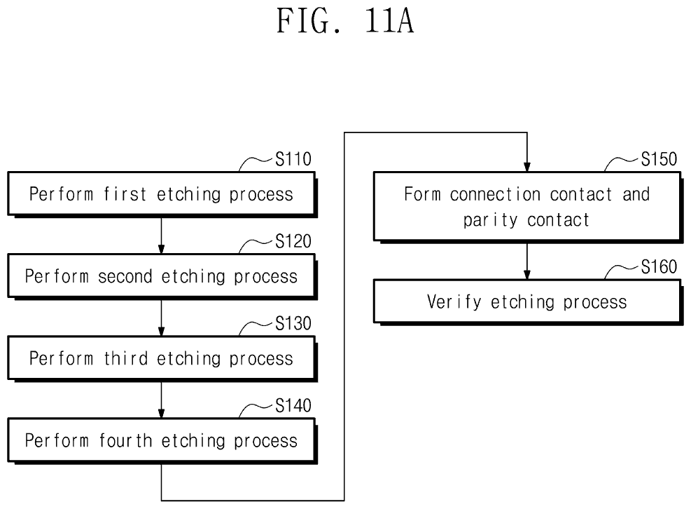

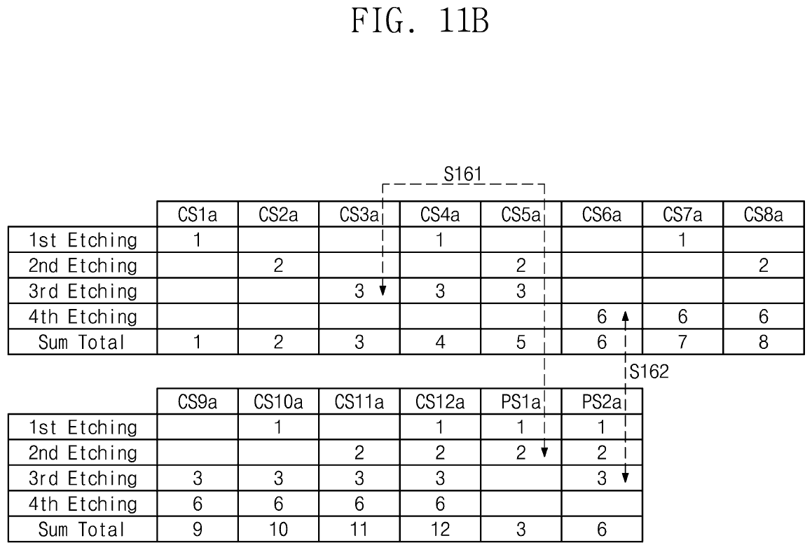

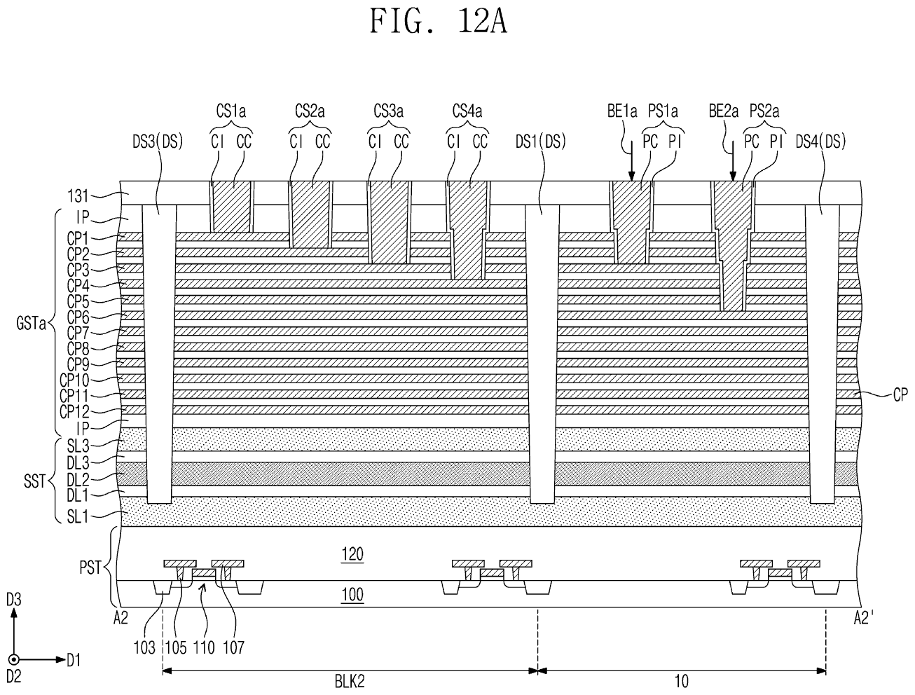

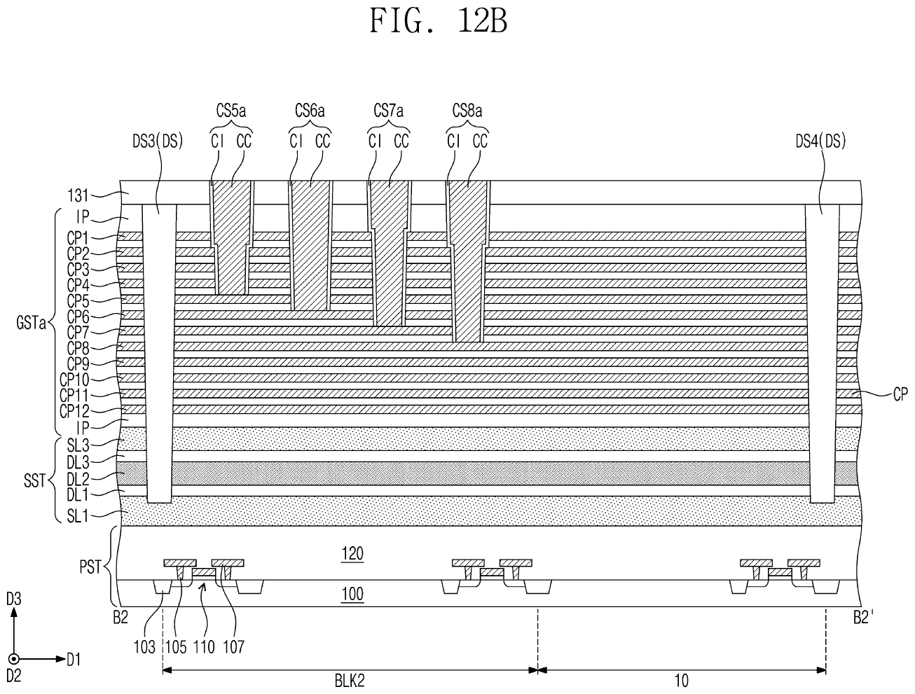

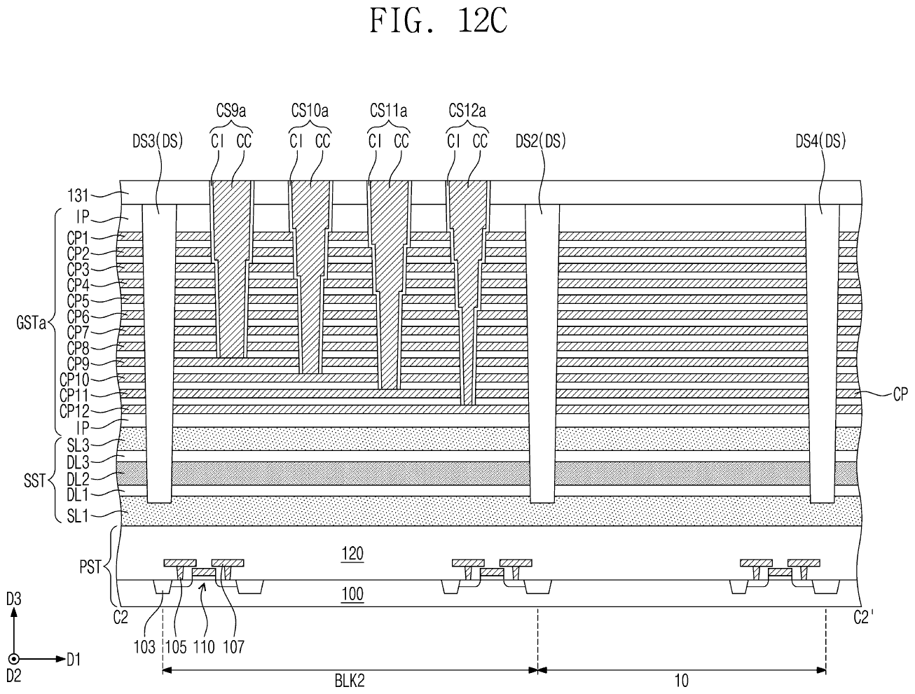

FIGS. 11A and 11B illustrate diagrams showing a method of manufacturing connection contact structures and parity contact structures according to FIGS. 10A to 10D. FIGS. 12A, 12B, and 12C illustrate cross-sectional views showing a method of fabricating a semiconductor device according to FIGS. 10A to 10D. In FIG. 11B, numerals may represent the number of sacrificial patterns newly exposed according to an etching process. Except that discussed below, a method of fabricating a semiconductor device according to FIGS. 11A, 11B, 12A, 12B, and 12C may be similar to the method of fabricating a semiconductor device according to FIGS. 3A to 9D.

Referring to FIGS. 11A, 11B, 12A, 12B, and 12C, the formation of the first to twelfth connection contact structures CS1a to CS12a and the first and second parity contact structures PS1a and PS2a may include performing a first etching process (S110), performing a second etching process (S120), performing a third etching process (S130), performing a fourth etching process (S140), forming a connection contact and a parity contact (S150), and verifying an etching process (S160).

In the first etching process S110, a hole may be formed to newly expose one sacrificial pattern on each of positions for the formation of the first, fourth, seventh, tenth, and twelfth connection contact structures CS1a, CS4a, CS7a, CS10a, and CS12a and the first and second parity contact structures PS1a and PS2a (see FIG. 11B).

In the second etching process S120, a hole may be formed to newly expose two sacrificial patterns on each of positions for the formation of the second, fifth, eight, eleventh, and twelfth connection contact structures CS2a, CS5a, CS8a, CS11a, and CS12a and the first and second parity contact structures PS1a and PS2a (see FIG. 11B).

In the third etching process S130, a hole may be formed to newly expose three sacrificial patterns on each of positions for the formation of the third, fourth, fifth, ninth, eleventh, and twelfth connection contact structures CS3a, CS4a, CS5a, CS9a, CS10a, CS11a, and CS12a and the second parity contact structure PS2a (see FIG. 11B).

In the fourth etching process S140, a hole may be formed to newly expose six sacrificial patterns on each of positions for the formation of the sixth, seventh, eighth, ninth, tenth, eleventh, and twelfth connection contact structures CS6a, CS7a, CS8a, CS9a, CS10a, CS11a, and CS12a (see FIG. 11B).

Connection contact dielectric layers CI and parity contact dielectric layers PI may be formed. The sacrificial patterns may be replaced with conductive patterns CP1 to CP15. Connection contacts CC and parity contacts PC may be formed (S150). An etching process may be verified (S160). A first electron beam BE1a may be irradiated to the parity contact PC of the first parity contact structure PS1a and the connection contact CC of the third connection contact structure CS3a, and comparing colors and/or brightness of light emitted from the parity contact PC of the first parity contact structure PS1a by the first electron beam BE1a and from the connection contact CC of the third connection contact structure CS3a by the first electron beam BE1a (S161). The comparison of the colors and/or brightness of light may determine whether the parity contact PC of the first parity contact structure PS1a and the connection contact CC of the third connection contact structure CS3a are electrically connected to the third conductive pattern CP3, and may also determine whether the third etching process S130 was performed to an appropriate depth.

A second electron beam BE2a may be irradiated to the parity contact PC of the second parity contact structure PS2a and the connection contact CC of the sixth connection contact structure CS6a, and comparing colors and/or brightness of light emitted from the parity contact PC of the second parity contact structure PS2a by the second electron beam BE2a and from the connection contact CC of the sixth connection contact structure CS6a by the second electron beam BE2a (S162). The comparison of the colors and/or brightness of light may determine whether the parity contact PC of the second parity contact structure PS2a and the connection contact CC of the sixth connection contact structure CS6a are electrically connected to the sixth conductive pattern CP6, and may also determine whether the fourth etching process S140 was performed to an appropriate depth.

In some embodiments, the second block BLK2 and the parity region 10 of the semiconductor device may include 12×N conductive patterns, and the semiconductor device may be fabricated through an etching process and an etching verification process that are performed N+3 times (where, Nis 1, 2, 4, 8, 16, . . . ).

In a method of fabricating a semiconductor device according to some embodiments, the third etching process and the fourth etching process may be verified without the parity etching process. Therefore, it may be possible to save cost and time required for the semiconductor device.

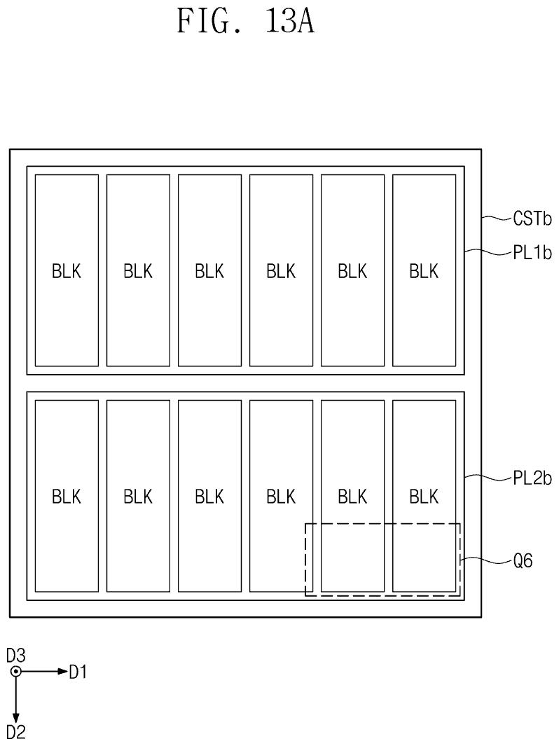

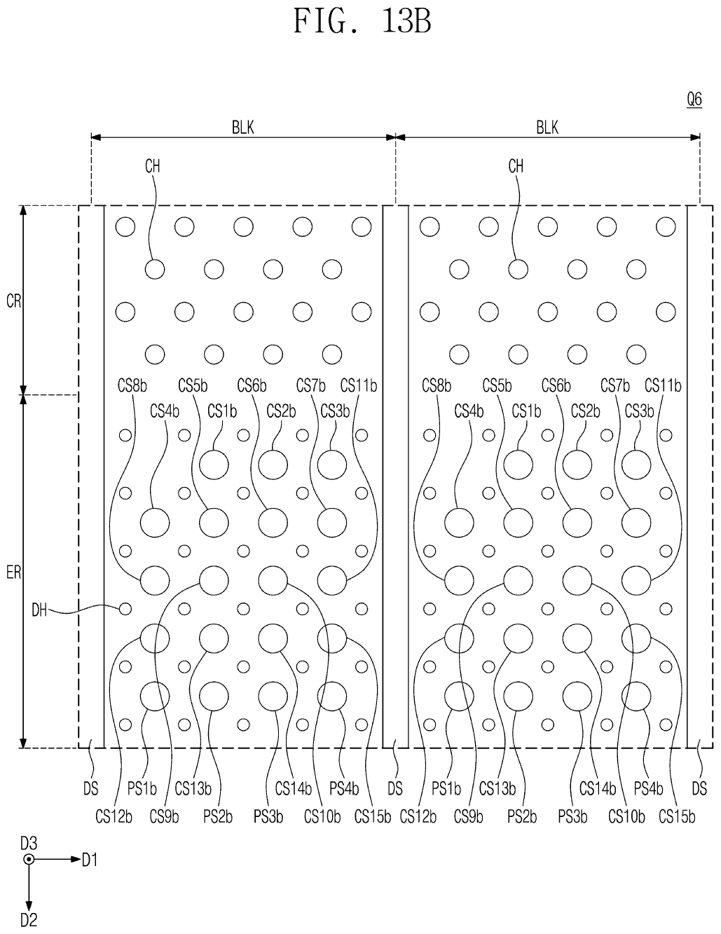

FIG. 13A illustrates a plan view showing a semiconductor device according to some embodiments. FIG. 13B illustrates an enlarged view showing section Q6 of FIG. 13A. Except that discussed below, a semiconductor device according to FIGS. 13A and 13B may be similar to the semiconductor device according to FIGS. 2A to 2K.

Referring to FIG. 13A, a memory cell structure CSTb of the semiconductor device may include a first plane PL1b and a second plane PL2b. Each of the first and second planes PL1b and PL2b may include a plurality of blocks BLK.

Referring to FIG. 13B, each of the blocks BLK may include first to fifteenth connection contact structures CS1b to CS15b and first to fourth parity contact structures PS1b to PS4b. The first to fifteenth connection contact structures CS1b to CS15b and the first to fourth parity contact structures PS1b to PS4b may be disposed on the extension region ER.

The first to fifteenth connection contact structures CS1b to CS15b and the first to fourth parity contact structures PS1b to PS4b may be disposed between two neighboring separation structures DS (in the first direction D1).

A distance in the second direction D2 between each of the first to fifteenth connection contact structures CS1b to CS15b and the memory channel structure CH may be less than a distance in the second direction D2 between each of the first to fourth parity contact structures PS1b to PS4b and the memory channel structure CH.

The first to fifteenth connection contact structures CS1b to CS15b may have a similar structure as that of the first to fifteenth connection contact structures CS1 to CS15 discussed in FIGS. 2A to 2K. The first to fourth parity contact structures PS1b to PS4b may have a similar structure as that of the first to fourth parity contact structures PS1 to PS4 discussed in FIGS. 2A to 2K.

The first to fourth parity contact structures PS1b to PS4b may be used to determine whether an etching process was properly performed in a process for forming the first to fifteenth connection contact structures CS1b to CS15b.

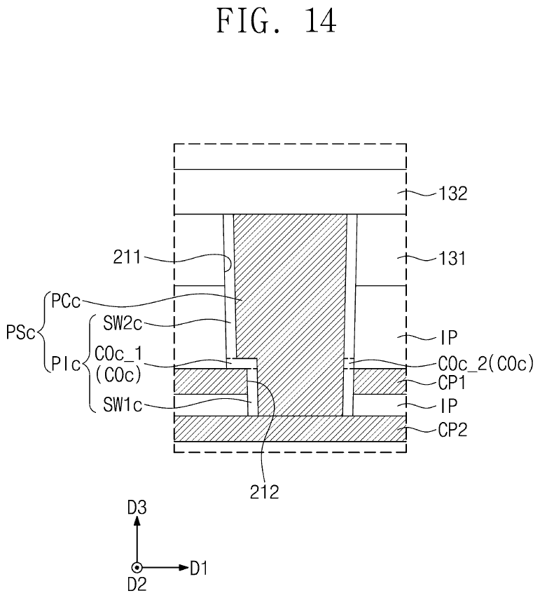

FIG. 14 illustrates an enlarged cross-sectional view showing a parity contact structure according to some embodiments. Except that discussed below, a semiconductor device according to FIG. 14 may be similar to the semiconductor device according to FIGS. 2A to 2K.

Referring to FIG. 14, a parity contact structure PSc may include a parity contact PCc and a parity contact dielectric layer PIc. The parity contact dielectric layer PIc may include a first sidewall part SW1c, a second sidewall part SW2c, and a connection part COc. The connection part COc may include a first part COc_1 and a second part COc_2. The first part COc_1 and the second part COc_2 of the connection part COc may be portions that are spaced apart in the first direction D1 from each other across the parity contact PCc.

A width in the first direction D1 of the first part COc_1 of the connection part COc may be greater than a width in the first direction D1 of the second part COc_2 of the connection part COc. The first part COc_1 of the connection part COc may have an upper surface (e.g., a top surface) in contact with the parity contact PCc. The first part COc_1 of the connection part COc may have a lower surface (e.g., a bottom surface) in contact with the first conductive pattern CP1. The second part COc_2 of the connection part COc may not be in contact with the first conductive pattern CP1. The second part COc_2 of the connection part COc may have an inner sidewall coplanar with those of the first and second sidewall parts SW1c and SW2c. The second part COc_2 of the connection part COc may have an outer sidewall coplanar with those of the first and second sidewall parts SW1c and SW2c. In some embodiments, the second part Coc_2 of the connection part COc may be connected to the first and second sidewall parts SW1c and SW2c without a visible bend, a directional change, or a visible boundary therebetween.

The parity contact structure PSc may be formed by a first etching process for forming a first hole 211 and a second etching process for forming a second hole 212. A process deviation of the first etching process and the second etching process may cause a change in shape of the first part COc_1 and the second part COc_2 of the connection part COc.

In some embodiments, a connection contact structure may have a similar shape as that of the parity contact structure PSc.

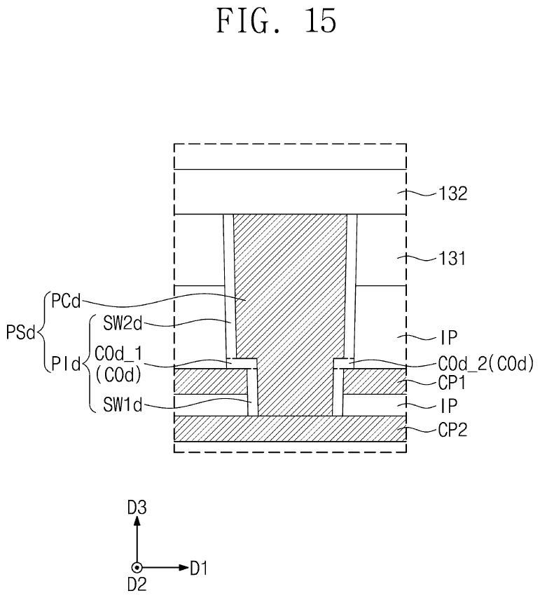

FIG. 15 illustrates an enlarged cross-sectional view showing a parity contact structure according to some embodiments. Except that discussed below, a semiconductor device according to FIG. 15 may be similar to the semiconductor device according to FIGS. 2A to 2K.

Referring to FIG. 15, a parity contact structure PSd may include a parity contact PCd and a parity contact dielectric layer PId. The parity contact dielectric layer PId may include a first sidewall part SW1d, a second sidewall part SW2d, and a connection part COd. The connection part Cod may include a first part COd_1 and a second part COd_2. A width in the first direction D1 of the first part COd_1 of the connection part COd may be greater than a width in the first direction D1 of the second part COd_2 of the connection part COd. The first part COd_1 and the second part COd_2 of the connection part COd may have their upper surfaces (e.g., top surfaces) in contact with the parity contact PCd. The first part COd_1 and the second part COd_2 of the connection part COd may have their lower surfaces (e.g., bottom surfaces) in contact with an upper surface (e.g., a top surface) of the first conductive pattern CP1.

In some embodiments, a connection contact structure may have a similar shape as that of the parity contact structure PSd.

In a semiconductor device according to some embodiments of the present inventive concepts, a parity contact structure may be included to verify an etching process for forming a connection contact structure and to improve reliability of the semiconductor device.

Although the present invention has been described in connection with some embodiments of the present inventive concepts illustrated in the accompanying drawings, it will be understood by one of ordinary skill in the art that variations in form and detail may be made therein without departing from the scope of the present inventive concepts. The above disclosed embodiments should thus be considered illustrative and not restrictive. Moreover, the embodiments discussed above may be combined with each other if necessary.

What is claimed is:

1. A semiconductor device, comprising:
a first conductive pattern;
a second conductive pattern spaced apart in a first direction from the first conductive pattern, wherein the first direction is perpendicular to an upper surface of the first conductive pattern;
a memory channel structure that extends in the first conductive pattern and the second conductive pattern in the first direction;
a first connection contact structure that extends in the second conductive pattern in the first direction and is electrically connected to the first conductive pattern; and
a first parity contact structure that extends in the second conductive pattern in the first direction and is electrically connected to the first conductive pattern,
wherein the first connection contact structure includes:
a first connection contact; and
a first connection contact dielectric layer that extends around the first connection contact,
wherein the first parity contact structure includes:
a first parity contact; and
a first parity contact dielectric layer that extends around the first parity contact,
wherein the first parity contact dielectric layer includes:
a sidewall part in contact with the upper surface of the first conductive pattern and a first sidewall of the second conductive pattern; and
a connection part connected to the sidewall part,
wherein a lower surface of the connection part of the first parity contact dielectric layer is in contact with an upper surface of the second conductive pattern.

2. The semiconductor device of claim 1, wherein
a lower surface of the sidewall part of the first parity contact dielectric layer is in contact with the upper surface of the first conductive pattern, and
an outer sidewall of the sidewall part of the first parity contact dielectric layer is in contact with the first sidewall of the second conductive pattern.

3. The semiconductor device of claim 1, wherein an outer sidewall of the first connection contact dielectric layer is in contact with a second sidewall of the second conductive pattern.

4. The semiconductor device of claim 1, wherein a length in the first direction of the first connection contact dielectric layer is equal to a length in the first direction of the first parity contact dielectric layer.

5. The semiconductor device of claim 1, further comprising:
a second connection contact structure electrically connected to the second conductive pattern; and
a second parity contact structure electrically connected to the second conductive pattern,
wherein the second connection contact structure includes:
a second connection contact in contact with the second conductive pattern; and
a second connection contact dielectric layer that extends around the second connection contact,
wherein the second parity contact structure includes:
a second parity contact in contact with the second conductive pattern; and
a second parity contact dielectric layer that extends around the second parity contact.

6. The semiconductor device of claim 5, further comprising: a third conductive pattern at farther than the second conductive pattern from the first conductive pattern in the first direction,
wherein the second parity contact dielectric layer includes:
a sidewall part in contact with the upper surface of the second conductive pattern; and
a connection part connected to the sidewall part of the second parity contact dielectric layer,
wherein the sidewall part of the second parity contact dielectric layer is in contact with a sidewall of the third conductive pattern, and
wherein a lower surface of the connection part of the second parity contact dielectric layer is in contact with an upper surface of the third conductive pattern.

7. The semiconductor device of claim 1, further comprising:
a first separation structure;
a second separation structure,
wherein the first conductive pattern includes:
a first conductive part in contact with the first connection contact;
a second conductive part in contact with the first parity contact; and
a third conductive part between the first conductive part and the second conductive part in a second direction,
wherein the second direction is parallel with the upper surface of the first conductive pattern,
wherein the first separation structure and the second separation structure are between the first conductive part and the second conductive part in the second direction,
wherein the third conductive part is between the first separation structure and the second separation structure in a third direction, and
wherein the third direction is parallel with the upper surface of the first conductive pattern and intersects the second direction.

8. A semiconductor device, comprising:
a gate stack structure that includes a plurality of conductive patterns including a first conductive pattern;
a memory channel structure that extends in the gate stack structure;
a first connection contact structure electrically connected to the first conductive pattern; and
a first parity contact structure electrically connected to the first conductive pattern,
wherein the first connection contact structure includes:
a first connection contact; and
a first connection contact dielectric layer that extends around the first connection contact,
wherein the first parity contact structure includes:
a first parity contact; and
a first parity contact dielectric layer that extends around the first parity contact,
wherein the first parity contact includes a first part and a second part on the first part, and
wherein the second part of the first parity contact includes a lower surface that connects a sidewall of the first part of the first parity contact to a sidewall of the second part of the first parity contact.

9. The semiconductor device of claim 8, wherein a minimum width of the first connection contact in a direction is greater than a minimum width of the first parity contact in the direction, and
wherein the direction is parallel with an upper surface of the first conductive pattern.

10. The semiconductor device of claim 8,
wherein the conductive patterns further include a second conductive pattern on the first conductive pattern, and
wherein the first parity contact dielectric layer includes:
a first sidewall part in contact with an upper surface of the first conductive pattern and a sidewall of the second conductive pattern; and
a connection part in contact with an upper surface of the second conductive pattern.

11. The semiconductor device of claim 10, wherein the lower surface of the second part of the first parity contact is in contact with an upper surface of the connection part of the first parity contact dielectric layer.

12. The semiconductor device of claim 10,
wherein the conductive patterns further include a third conductive pattern on the second conductive pattern,
wherein the first parity contact dielectric layer further includes a second sidewall part in contact with a sidewall of the third conductive pattern, and
wherein a sidewall of the second part of the first parity contact is in contact with an inner sidewall of the second sidewall part of the first parity contact dielectric layer.

13. The semiconductor device of claim 8, wherein a maximum width of the second part of the first parity contact in a direction is equal to a maximum width of the first connection contact in the direction, and
wherein the direction is parallel with an upper surface of the first conductive pattern.

14. The semiconductor device of claim 8, wherein a distance between the memory channel structure and the first connection contact structure in a direction is less than a distance between the memory channel structure and the first parity contact structure in the direction, and
wherein the direction is parallel with an upper surface of the first conductive pattern.

15. The semiconductor device of claim 8, wherein a maximum width of the first part of the first parity contact in a direction is less than a minimum width of the second part of the first parity contact in the direction, and
wherein the direction is parallel with an upper surface of the first conductive pattern.

16. The semiconductor device of claim 8, wherein a number of the conductive patterns in contact with the first parity contact structure and the first connection contact structure is a multiple of four.

17. The semiconductor device of claim 8, wherein a number of the conductive patterns in contact with the first parity contact structure and the first connection contact structure is a multiple of three.

18. The semiconductor device of claim 8, further comprising: a separation structure between the first parity contact structure and the first connection contact structure in a first direction,
wherein the separation structure extends in the gate stack structure in a second direction,
wherein the first direction is parallel with an upper surface of the first conductive pattern, and
wherein the second direction is perpendicular to the upper surface of the first conductive pattern.

19. An electronic system, comprising:
a main board;
a semiconductor device on the main board; and
a controller on the main board and electrically connected to the semiconductor device,
wherein the semiconductor device includes:
a first conductive pattern;
a second conductive pattern spaced apart in a first direction from the first conductive pattern, wherein the first direction is perpendicular to an upper surface of the first conductive pattern;
a third conductive pattern spaced apart in the first direction from the second conductive pattern;
a memory channel structure that extends in the first, second, and third conductive patterns in the first direction;
a first connection contact structure electrically connected to the first conductive pattern;
a first parity contact structure electrically connected to the first conductive pattern;
a second connection contact structure that extends in the first conductive pattern in the first direction and is electrically connected to the second conductive pattern;
a second parity contact structure that extends in the first conductive pattern in the first direction and is electrically connected to the second conductive pattern;
a third connection contact structure that extends in the first and second conductive patterns in the first direction and is electrically connected to the third conductive pattern; and
a third parity contact structure that extends in the first and second conductive patterns in the first direction and is electrically connected to the third conductive pattern,
wherein each of the first, second, and third connection contact structures includes a connection contact and a connection contact dielectric layer that extends around the connection contact,
wherein the first parity contact structure includes a first parity contact and a first parity contact dielectric layer that extends around the first parity contact,
wherein the second parity contact structure includes a second parity contact and a second parity contact dielectric layer that extends around the second parity contact,
wherein the third parity contact structure includes a third parity contact and a third parity contact dielectric layer that extends around the third parity contact,
wherein the third parity contact includes a first part, a second part on the first part, and a third part on the second part,
wherein a maximum width of the first part of the third parity contact in a second direction is less than a minimum width of the second part of the third parity contact in the second direction,
wherein a maximum width of the second part of the third parity contact in the second direction is less than a minimum width of the third part of the third parity contact in the second direction,
wherein the second parity contact includes a first part and a second part on the first part of the second parity contact,
wherein a maximum width of the first part of the second parity contact in the second direction is less than a minimum width of the second part of the second parity contact in the second direction,
wherein a minimum width of the first part of the third parity contact in the second direction is less than a minimum width of the first part of the second parity contact in the second direction, and
wherein the second direction is parallel with the upper surface of the first conductive pattern.

20. The electronic system of claim 19, wherein a maximum width of the third part of the third parity contact in the second direction is equal to a maximum width of the second part of the second parity contact in the second direction.
